(19) United States
(12) Patent Application Publication
(10) Pub. No.: US 2016/0360317 A1
(43) Pub. Date: Dec. 8, 2016

(54) AUDIO PROCESSING APPARATUS AND CONTROL METHOD THEREOF

(71) Applicant: SAMSUNG ELECTRONICS CO., LTD., Suwon-si (KR)

(72) Inventors: Jae-cheol LEE, Yongin-si (KR); Hae-jong KIM, Seoul (KR)

(73) Assignee: SAMSUNG ELECTRONICS CO., LTD., Suwon-si (KR)

(21) Appl. No.: 15/162,780

(22) Filed: May 24, 2016

(30) Foreign Application Priority Data
Jun. 2, 2015 (KR) 10-2015-0077835

(51) Int. Cl. H04R 3/12; H03F 3/185

(52) U.S. Cl. CPC H04R 3/12; H03F 3/185; H03F 2200/552; H04R 2420/01; H04R 2430/01

(57) ABSTRACT

An audio processing apparatus includes a signal receiver to receive a content signal; a first amplifier to output a first amplified signal of an audio signal extracted from the content signal; a second amplifier to output a second amplified signal of the audio signal, which has an inverted phase of the first amplified signal; a loudspeaker to produce a sound corresponding to the audio signal; a switch to perform a switching operation so that at least one of the first amplified signal and the second amplified signal respectively amplified by and output from the first amplifier and the second amplifier can be selectively transmitted to the loudspeaker; and at least one processor configured to control the switching operation of the switch in accordance with a level of output power of the sound.

### CROSS-REFERENCE TO RELATED APPLICATIONS

This application claims priority from Korean Patent Application No. 10-2015-0077835 filed on Jun. 2, 2015 in the Korean Intellectual Property Office, the disclosure of which is incorporated herein by reference.

### BACKGROUND

1. Field

Apparatuses and methods consistent with the exemplary embodiments relate to an audio processing apparatus, which extracts an audio signal from a transport stream of contents and produces a sound based on the audio signal, and a control method thereof, and more particularly to an audio processing apparatus, which has an improved amplification structure to not only raise an audio output but also enhance an energy efficiency while an audio signal is processed to be amplified, and a control method thereof.

2. Description of the Related Art

An audio processing apparatus reproduces an audio signal to output a sound through a loudspeaker. The audio processing apparatus may be achieved to simply output only a sound, but is mostly achieved by a video processing apparatus or display apparatus capable of reproducing an image and a sound.

A video processing apparatus processes a video signal/video data received from the exterior in accordance with various video processing processes. The video processing apparatus may display an image based on the processed video data on its own display panel, or output the processed video signal to another display apparatus provided with a panel so that the display apparatus can display an image based on the processed video signal. That is, the video processing apparatus includes the panel capable of displaying an image or does not include a panel but can still process the video data. For example, the former may include a television (TV), and the latter may include a set-top box.

Video contents contain audio and additional data as well as video data. For example, a transport stream received in the video processing apparatus includes a video signal component and an audio signal component, and the video processing apparatus respectively processes the components by individual processes so that the video signal component can be displayed as an image on the display panel and the audio signal component can be output as a sound through the loudspeaker.

To process the respective signal components contained in the transport stream, there may be needed hardware structures individually provided for processing the corresponding signal components. For example, to process and output the audio signal component extracted from the transport stream, the video processing apparatus includes an amplifier for amplifying the audio signal in accordance with a selected audio volume, and a loudspeaker for outputting a sound based on the audio signal component amplified by the amplifier. In particular, the amplifier includes various electronic circuits that operate under control of a controller. Here, a design direction of increasing the output power of the audio signal may make the circuits become relatively complicated.

However, if the hardware design for the amplifier is directed to increasing the output power of the audio signal, the output power is increased but energy efficiency is lowered. The audio volume desired by a user may be varied depending on various view environments, the kind of contents, etc. If the audio volume desired by a user is low, the output power of the amplifier has to be also lowered. In this case, the amplifier cannot make use of the hardware designed for increasing the output power, and thus has low energy efficiency.

Accordingly, when a circuit structure for increasing the output power is applied to an audio amplifier of the video processing apparatus, there is a need of a structure or method to keep the energy efficiency as high as possible.

### SUMMARY

Additional aspects and/or advantages will be set forth in part in the description which follows and, in part, will be apparent from the description, or may be learned by practice of the invention.

According to an aspect of an exemplary embodiment, there is provided an audio processing apparatus including a signal receiver configured to receive a content signal; a first amplifier configured to output a first amplified signal of an audio signal extracted from the content signal; a second amplifier configured to output a second amplified signal of the audio signal, which has an inverted phase of the first amplified signal; a loudspeaker configured to produce a sound corresponding to the audio signal; a switch configured to perform a switching operation so that at least one of the first amplified signal and the second amplified signal respectively amplified by and output from the first amplifier and the second amplifier can be selectively transmitted to the loudspeaker; and at least one processor configured to control the switching operation of the switch in accordance with a level of output power of the sound. Thus, both the first amplified signal and the second amplified signal are used to cope with the high output power if the level of the output power adjusted to be high, and only the first amplified signal is used without the second amplified signal to thereby enhance energy efficiency if the level of the output power is adjusted to be low.

The at least one processor may control the switch to allow the second amplified signal to be transmitted from the second amplifier to the loudspeaker if the level of the output power is adjusted to be higher than a preset threshold level, and may control the switch to prevent the switch to prevent the second amplified signal from being transmitted from the second amplifier to the loudspeaker if the level of the output power is adjusted not to be higher than the threshold level. Here, the threshold level for the at least one processor may be a quarter of the maximum level of the output power of when both the first amplified signal and the second amplified signal are transmitted to the loudspeaker. Thus, it is easy to prevent the second amplified signal from being transmitted to the loudspeaker in order to enhance the energy efficiency.

Further, the at least one processor may activate the second amplifier to perform an amplifying operation if the level of the output power is adjusted to be higher than the preset threshold level, and may inactivate the second amplifier not to perform the amplifying operation if the level of the output power is adjusted not to be higher than the threshold level. Thus, it is possible to reduce power consumed by the second amplifier in order to enhance the energy efficiency instead of raising the output power.

Further, the loudspeaker may include a first terminal for receiving the first amplified signal and a second terminal for receiving the second amplified signal, and the at least one processor may control the switch to electrically connect the second terminal and the second amplifier if the level of the output power is adjusted to be higher than the preset threshold level and may control the switch to connect the second terminal and the ground if the level of the output power is adjusted not to be higher than the preset threshold level. With this simple structure, it is possible to prevent the second amplified signal from being transmitted from the second amplifier to the loudspeaker.

Further, each of the first amplifier and the second amplifier may include two field effect transistors (FETs), and the two FETs may include a first FET and a second FET, in which a source electrode of the first FET and a drain electrode of the second FET are connected in series with each other. Thus, a structure for amplifying the audio signal is achieved by two FETs.

Further, the at least one processor may process a positive voltage and a negative voltage to be all applied to the first amplifier and the second amplifier. Thus, it is possible to raise the output power more than that of when only the positive voltage is used in amplification of both the first amplifier and the second amplifier or when the positive voltage and the negative voltage are used in amplification of the first amplifier.

Further, the audio processing apparatus may further include a user input, in which the level of the output power corresponds to an audio volume adjusted through the user input. Thus, it is easy for a user to adjust the level of the output power.

According to an aspect of an exemplary embodiment, there is provided a method of controlling an audio processing apparatus, the method including: receiving a content signal; by a first amplifier, outputting a first amplified signal of an audio signal extracted from the content signal; by a second amplifier, outputting a second amplified signal of the audio signal, which has an inverted phase of the first amplified signal; by a switch, performing a switching operation in accordance with a level of output power of the sound so that at least one of the first amplified signal and the second amplified signal respectively amplified by and output from the first amplifier and the second amplifier can be selectively transmitted to a loudspeaker; and by the loudspeaker, producing a sound corresponding to the audio signal. Thus, both the first amplified signal and the second amplified signal are used to cope with the high output power if the level of the output power adjusted to be high, and only the first amplified signal is used without the second amplified signal to thereby enhance energy efficiency if the level of the output power is adjusted to be low.

The performing the switching operation by the switch may include: allowing the second amplified signal to be transmitted from the second amplifier to the loudspeaker if the level of the output power is adjusted to be higher than a preset threshold level; and preventing the switch to prevent the second amplified signal from being transmitted from the second amplifier to the loudspeaker if the level of the output power is adjusted not to be higher than the threshold level. Here, the threshold level may be a quarter of the maximum level of the output power of when both the first amplified signal and the second amplified signal are transmitted to the loudspeaker. Thus, it is easy to prevent the second amplified signal from being transmitted to the loudspeaker in order to enhance the energy efficiency.

Further, the method may further include activating the second amplifier to perform an amplifying operation if the level of the output power is adjusted to be higher than the preset threshold level; and inactivating the second amplifier not to perform the amplifying operation if the level of the output power is adjusted not to be higher than the threshold level. Thus, it is possible to reduce power consumed by the second amplifier in order to enhance the energy efficiency instead of raising the output power.

Further, the loudspeaker may include a first terminal for receiving the first amplified signal and a second terminal for receiving the second amplified signal, and the performing the switching operation by the switch may include electrically connecting the second terminal and the second amplifier if the level of the output power is adjusted to be higher than the preset threshold level, and connecting the second terminal and the ground if the level of the output power is adjusted not to be higher than the preset threshold level. With this simple structure, it is possible to prevent the second amplified signal from being transmitted from the second amplifier to the loudspeaker.

Further, a positive voltage and a negative voltage may be all applied to the first amplifier and the second amplifier. Thus, it is possible to more raise the output power than that of when only the positive voltage is used in amplification of both the first amplifier and the second amplifier or when the positive voltage and the negative voltage are used in amplification of the first amplifier.

Further, the level of the output power may correspond to an audio volume adjusted through a user input. Thus, it is easy for a user to adjust the level of the output power.

### BRIEF DESCRIPTION OF THE DRAWINGS

The above and/or other aspects will become apparent and more readily appreciated from the following description of exemplary embodiments, taken in conjunction with the accompanying drawings, in which:

FIG. 1 illustrates a video processing apparatus according to a first exemplary embodiment;

FIG. 2 is a block diagram of the video processing apparatus of FIG. 1;

FIG. 3 is a block diagram of a signal processor in the video processing apparatus of FIG. 1;

FIG. 4 is a block diagram of an audio processor in the signal processor of FIG. 3;

FIG. 5 is a block diagram of an amplification system in the audio processor of FIG. 4;

FIG. 6 is a circuit diagram of an amplifier according to the first exemplary embodiment;

FIG. 7 is a circuit diagram of an amplifier according to a second exemplary embodiment;

FIG. 8 is a graph showing respective output waveforms of a single ended (SE) type amplifier and a bridge-tied load (BTL) type amplifier if they have the same output power;

FIG. 9 is a block diagram of an amplification system according to a third exemplary embodiment;

FIG. 10 is a circuit diagram of the amplification system according to the third exemplary embodiment, showing an operation when an audio volume is higher than a threshold level;

FIG. 11 is a circuit diagram of the amplification system according to the third exemplary embodiment, showing an operation when the audio volume is equal to or lower than a threshold level;

FIGS. 12 and 13 are flowcharts showing that the amplification system of the video processing apparatus according to the third exemplary embodiment amplifies an audio signal of a certain channel to control a sound output through a loudspeaker;

FIG. 14 is a block diagram of an amplification system according to a fourth exemplary embodiment;

FIG. 15 is a flowchart showing that the amplification system according to the fourth exemplary embodiment amplifies an audio signal of a certain channel to control a sound output through a loudspeaker;

FIG. 16 illustrates a user interface (UI) of adjusting a threshold level for determining an operation mode of an amplification system in a video processing apparatus according to a fifth exemplary embodiment;

FIG. 17 is a flowchart showing control of the video processing apparatus according to the fifth exemplary embodiment;

FIG. 18 shows a table where operation modes of an amplification system are set according to genres of contents in a video processing apparatus according to a sixth exemplary embodiment;

FIG. 19 illustrates a UI of adjusting the table where the operation modes of the amplification system are set according to the genres of the contents in the video processing apparatus according to the sixth exemplary embodiment;

FIG. 20 is a flowchart showing control of the video processing apparatus according to the sixth exemplary embodiment;

FIG. 21 is a flowchart showing control of a video processing apparatus according to a seventh exemplary embodiment;

FIG. 22 shows a table where audio amplification modes are set according to audio languages of video contents in a video processing apparatus according to an eighth exemplary embodiment

FIG. 23 is a flowchart showing control of the video processing apparatus according to the eighth exemplary embodiment;

FIG. 24 is a block diagram of an audio processing apparatus according to a ninth exemplary embodiment; and

FIG. 25 is a block diagram of an audio processing apparatus according to a tenth exemplary embodiment.

### DETAILED DESCRIPTION

Below, exemplary embodiments will be described in detail with reference to accompanying drawings. The following descriptions of the exemplary embodiments are made by referring to elements shown in the accompanying drawings, in which like numerals refer to like elements having substantively the same functions.

In the description of the exemplary embodiments, an ordinal number used in terms such as a first element, a second element, etc. is employed for describing variety of elements, and the terms are used for distinguishing between one element and another element. Therefore, the meanings of the elements are not limited by the terms, and the terms are also used just for explaining the corresponding embodiment without limiting the idea of the invention.

Further, the exemplary embodiments will describe only elements directly related to the idea of the invention, and description of the other elements will be omitted. However, it will be appreciated that the elements, the descriptions of which are omitted, are not unnecessary to realize the apparatus or system according to the exemplary embodiments. In the following descriptions, terms such as “include” or “have” refer to presence of features, numbers, steps, operations, elements or combination thereof, and do not exclude presence or addition of one or more other features, numbers, steps, operations, elements or combination thereof.

The present inventive concept to be described in the following exemplary embodiments is related to an audio amplification process, and may be basically applicable to general electronic apparatuses having an audio processing function. As an example of the electronic apparatuses according to the present inventive concept, a video processing apparatus capable of processing an image to be displayable will be described.

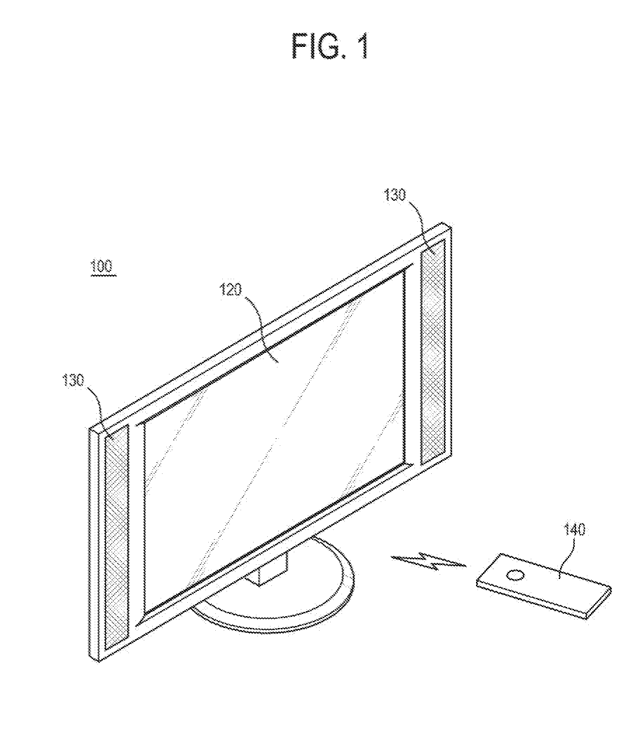

FIG. 1 illustrates a video processing apparatus 100 according to a first exemplary embodiment;

As shown in FIG. 1, the video processing apparatus 100 according to the first exemplary embodiment is achieved by a television (TV), but not limited thereto. Alternatively, the video processing apparatus may be achieved by a tablet personal computer (PC), a mobile phone, a multimedia player, an electronic frame, a digital signage and the like apparatus of displaying an image, or buy a set-top box and the like apparatus of processing an image without displaying it by itself. In addition, the present inventive concept may be applied to a general electronic apparatus for performing an audio process regardless of a video process.

The video processing apparatus 100 processes a transport stream of video contents received from the exterior and displays it as an image. The transport stream of the video contents may be a radio frequency (RF) broadcast signal received from a transmitter (not shown) of a broadcasting station, a data packet received from a server (not shown) through a network, or a signal reproduced and transmitted from a multimedia player (not shown) locally connected to the video processing apparatus 100. In addition, the transport stream of the video contents may be generated based on data stored in the video processing apparatus 100.

Generally, the video contents may further include audio data or additional data as well as video data. For example, the video processing apparatus 100 extracts a video signal component and an audio signal component from the transport stream, and processes and outputs the respective components. To this end, the video processing apparatus 100 includes a display 120 for displaying an image, and a loudspeaker 130 for producing a sound. At this time, the video processing apparatus 100 synchronizes display of an image with production of a sound, thereby normally providing the video contents to a user.

The video processing apparatus 100 allows a user to adjust various characteristics of the sound produced by the loudspeaker 130 like as if she or he adjusts various characteristics of the image displayed on the display 120. This adjustment of a user may be implemented through the user input 140.

Among various characteristics of the sound, an audio volume is one of the most often adjusted characteristics. The video processing apparatus 100 designates the audio volume of a preset default level when a sound is first produced through the loudspeaker 130. Then, the video processing apparatus 100 controls amplification of the audio signal and thus adjusts an audio volume output from the loudspeaker 130 in response to volume control input through a user input 140.

Below, the video processing apparatus 100 will be described in more detail.

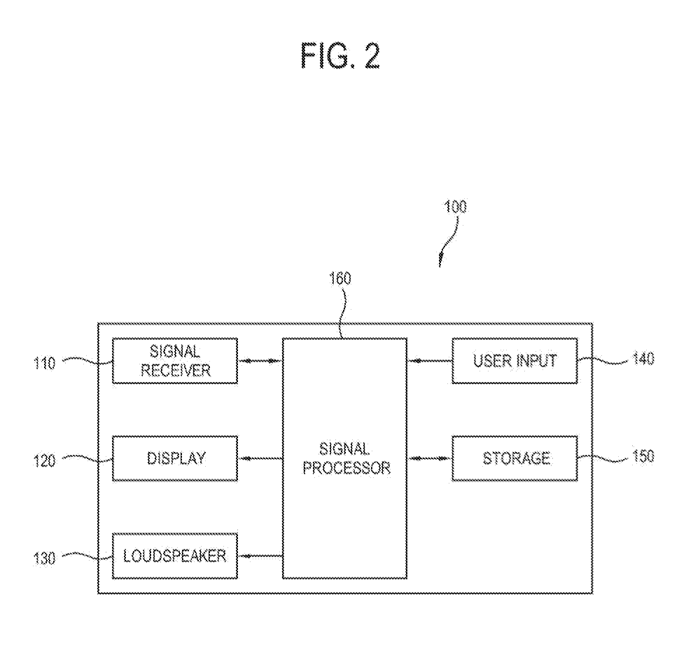

FIG. 2 is a block diagram of the video processing apparatus 100 of FIG. 1.

As shown in FIG. 2, the video processing apparatus 100 includes a signal receiver 110 for receiving the transport stream of the video contents from the exterior, the display 120 for displaying an image based on video data of the transport stream received in the signal receiver 110, the loudspeaker 130 for producing a sound based on audio data of the transport stream received in the signal receiver 110, the user input 140 for receiving a user's input, a storage 150 for storing data, and a signal processor 160 for controlling and calculating general operations of the video processing apparatus 100.

The signal receiver 110 receives transport streams from various video sources. The signal receiver 110 is not limited to only receiving a signal from the exterior, but may transmit a signal to the exterior, thereby performing interactive communication. The signal receiver 110 may be achieved by an assembly of communication ports or communication modules respectively corresponding to a plurality of communication standards, and its supportable protocols and communication targets are not limited to one kind or type. For example, the signal receiver 110 may include a radio frequency integrated circuit (RFIC) for receiving an RF signal, a wi-fi communication module (not shown) for wireless network communication, an Ethernet module (not shown) for wired network communication, and a universal serial bus (USB) port (not shown) for local connection with a USB memory (not shown) or the like.

The display 120 displays an image based on an image signal processed by the signal processor 160. There are no limits to the types of the display 120. For example, the display 120 may be achieved by various display types such as liquid crystal, plasma, a light-emitting diode, an organic light-emitting diode, a surface-conduction electron emitter, a carbon nano-tube, nano-crystal, etc.

The display 120 may include additional elements in accordance with the types of the panel in addition to the panel structure for displaying an image. For example, if the display 120 is achieved by the liquid crystal, the display 130 includes a liquid crystal display (LCD) panel (not shown), a backlight unit (not shown) for supplying light to the LCD panel, and a panel driving substrate (not shown) for driving the LCD panel (not shown).

The loudspeaker 130 produces a sound based on the audio signal processed by the signal processor 160. The loudspeaker 130 is provided to produce a sound having an audible frequency band of 20 Hz to 20 KHz, which can be perceived by a person who has no hearing problem. The loudspeakers 130 may be installed at various positions in consideration of processible audio channels and output frequencies, and their installation positions may for example be adjacent to the left and right edges of the display 120.

There are various kinds of loudspeaker 130 in accordance with frequency bands of an output sound. The loudspeaker 130 includes a sub-woofer corresponding to a frequency band of 20 Hz to 99 Hz, a woofer corresponding to a frequency band of 100 Hz to 299 Hz, a mid-woofer corresponding to a frequency band of 300 Hz to 499 Hz, a mid-range loudspeaker corresponding to a frequency band of 500 Hz to 2.9 KHz, a twitter corresponding to a frequency band of 3 KHz to 6.9 KHz, a super-twitter loudspeaker corresponding to a frequency band of 7 KHz to 20 KHz, etc., and one or more among them are selectively applied to the video processing apparatus 100.

The user input 140 transmits various preset control commands or information to the signal processor 160 in accordance with a user's control or input. The user input 140 transmits various events, which occurs by a user's control in accordance with a user's intention, to the signal processor 160. The user input 140 may be variously achieved in accordance with information input methods. For example, the user input 140 may include a button provided on an outer side of the video processing apparatus 100, a separate remote controller separated from the video processing apparatus 100, a touch screen formed integrally with the display 120, and an input device provided to communicate with the video processing apparatus 100.

The storage 150 stores various pieces of data under process and control of the signal processor 160. The storage 150 is accessed by the signal processor 160 and performs reading, writing, editing, deleting, updating or the like with regard to data. The storage 150 is achieved by a flash-memory, a hard-disc drive or other nonvolatile memory to preserve data regardless of supply of system power in the video processing apparatus 100.

The signal processor 160 performs various processes with regard to the transport stream received in the signal receiver 110. When the transport stream is received in the signal receiver 110, the signal processor 160 applies a video processing process to the video signal, and outputs the processed video signal to the display 120, thereby displaying an image on the display 120.

There are no limits to the kind of image processing process performed by the signal processor 160, and the video processing process may for example include demultiplexing for separating the transport stream into sub streams such as a video signal, an audio signal and additional data, decoding corresponding to video formats of a video signal, de-interlacing for converting a video signal from an interlaced type into a progressive type, scaling for adjusting a video signal to have a preset resolution, noise reduction for improving image quality, detail enhancement, frame refresh rate conversion, etc.

Since the signal processor 160 can perform various processes in accordance with the kinds and characteristics of signal or data, the process performable by the signal processor 160 is not limited to the video processing process. Further, data processible by the signal processor 160 is not limited to only data received in the signal receiver 110. For example, the signal processor 160 can perform an audio processing process with regard to an audio signal extracted from a transport stream, and output the processed audio signal to the loudspeaker 130. Further, if a user's voice is input to the video processing apparatus 100, the signal processor 160 may process the voice in accordance with a preset voice recognition processing process. The signal processor 160 is achieved by a system-on-chip (SOC), in which many functions are integrated, or an image processing board (not shown) where individual chip-sets for independently performing the processes are mounted to a printed circuit board.

The video processing apparatus 100 may have specifically different hardware components in accordance with the types of the video processing apparatus 100 and the functions supported by the video processing apparatus 100. For example, a hardware component to be tuned to a certain frequency for receiving a broadcast signal may be included if the video processing apparatus 100 is a TV or a set-top box, but may be excluded if the video processing apparatus 100 is a tablet PC.

Below, the signal processor 160 of when the video processing apparatus 100 is the TV will be described.

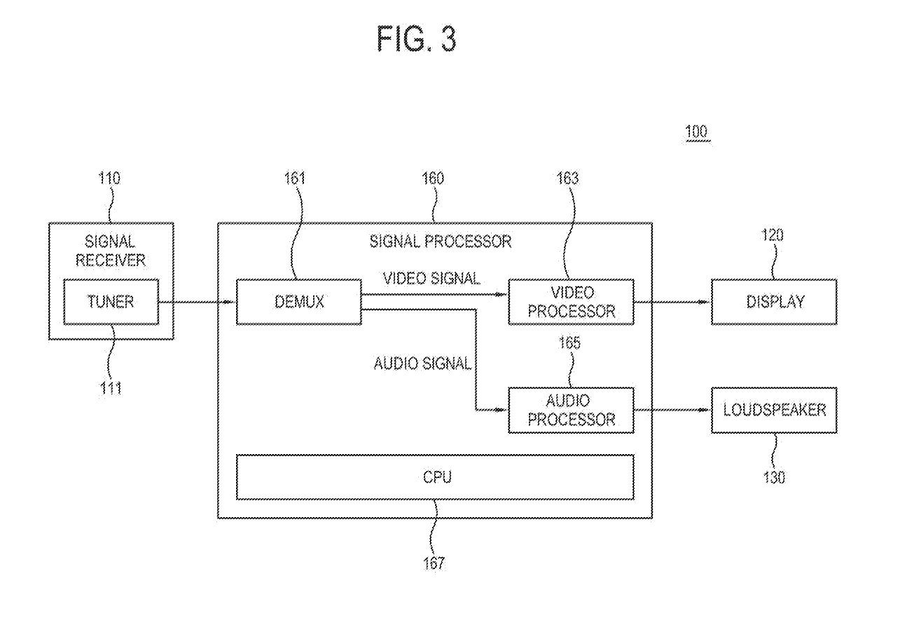

FIG. 3 is a block diagram of the signal processor 160. FIG. 3 shows only basic elements of the signal processor 160, and an actual product of the video processing apparatus 100 includes additional elements besides the elements described below.

As shown in FIG. 3, the signal receiver 110 includes a tuner 111 to be tuned to a certain frequency to receive a broadcast stream. Further, the signal processor 160 includes a deMUX 161 for dividing the broadcast stream received from the tuner 111 into a plurality of sub signals, a video processor 163 for processing a video signal among the sub signals output from the deMUX 161 in accordance with the video processing process and outputting the processed video signal to the display 120, an audio processor 165 for processing an audio signal among the sub signals output from the deMUX 161 in accordance with the audio processing process and outputting the processed audio signal to the loudspeaker 130, and a central processing unit (CPU) 167 performs calculation and control for the operations of the signal processor 160.

When a broadcast stream is received in an RF antenna (not shown), the tuner 111 is tuned to a frequency of a designated channel to receive a broadcast stream and converts the broadcast stream into a transport stream. The tuner 111 converts a high frequency of a carrier wave received via the antenna (not shown) into an intermediate frequency band and converts it into a digital signal, thereby generating a transport stream. To this end, the tuner 111 has an analog/digital (A/D) converter (not shown). Alternatively, the A/D converter (not shown) may be designed to be included in a demodulator (not shown) instead of the tuner 111.

The deMUX (or demultiplexer) 161 performs a reverse operation of the multiplexer (not shown). That is, the deMUX 161 connects one input terminal with a plurality of output terminals, and distributes a stream input to the input terminal to the respective output terminals in accordance with selection signals. For example, if there are four output terminals with respect to one input terminal, the deMUX 161 may select each of the four output terminals by combination of selection signals having two levels of 0 and 1.

In the case where the deMUX 161 is applied to the video processing apparatus 100, the deMUX 161 divides the transport stream received from the tuner 111 into the sub signals of a video signal and an audio signal and outputs them to the respective output terminals.

The deMUX 161 may use various methods to divide the transport stream into the sub signals. For example, the deMUX 161 divides the transport stream into the sub signals in accordance with packet identifiers (PID) given to packets in the transport stream. The sub signals in the transport stream are independently compressed and packetized according to channels, and the same PID is given to the packets corresponding to one channel so as to be distinguished from the packets corresponding to another channel. The deMUX 161 classifies the packets in the transport stream according to the PID, and extracts the sub signals having the same PID.

The video processor 163 decodes and scales the video signal output from the deMUX 161. To this end, the video processor 163 includes a decoder (not shown) that returns the video signal to a state before an encoding process by performing an opposite process to the encoding process with regard to the video signal encoded by a certain format, and a scaler (not shown) that scales the decoded video signal in accordance with the resolution of the display 120 or a separately designated resolution. If the video signal output from the deMUX 161 is not encoded by a certain format, i.e. not compressed, the decoder (not shown) of the video processor 163 does not process this video signal.

The CPU 167 is an element for performing central calculation to operate general elements in the signal processor 160, and plays a central role in basically parsing and calculating data. The CPU 167 internally includes a processor register (not shown) in which commands to be processed are stored; an arithmetic logic unit (ALU) (not shown) being in charge of comparison, determination and calculation; a control unit (not shown) for internally controlling the CPU 167 to analyze and carry out the commands; an internal bus (not shown), a cache (not shown), etc.

The CPU 167 performs calculation needed for operating the elements of the signal processor 160, such as the deMUX 161, the video processor 163 and the audio processor 165. Alternatively, some elements of the signal processor 160 may be designed to operate without the data calculation of the CPU 167 or by a separate microcontroller (not shown).

Below, the audio processor 165 will be described in more detail.

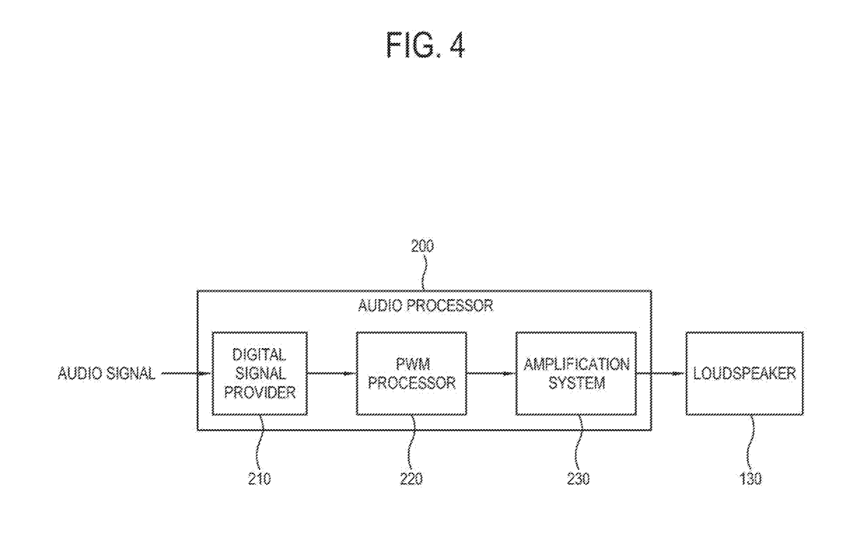

FIG. 4 is a block diagram of an audio processor 200. The audio processor 200 of FIG. 4 is the same as the audio processor 165 of FIG. 3.

As shown in FIG. 4, the audio processor 200 includes a digital signal provider 210 for outputting an audio signal, i.e. a digital signal, a pulse width modulation (PWM) processor 220 for outputting a PWM signal based on the digital signal output from the digital signal provider 210, and an amplification system 230 for amplifying the PWM signal output from the PWM processor 220.

The digital signal provider 210 performs pulse code modulation (PCM) to convert an input audio signal into a digital signal. To this end, the digital signal provider 210 includes a digital signal processor (DSP), a moving picture experts group (MPEG) converter integrated circuit (IC), etc.

The PWM processor 220 converts a PCM signal having a low amplitude output from the digital signal provider 210 into a PWM signal of low power.

The amplification system 230 amplifies the PWM signal of the low power output from the PWM processor 220 into a PWM signal through a semiconductor switch of a switching circuit, e.g. a field effect transistor (FET). For example, the amplification system 230 receives a PWM signal having a low level of about 3.3V and amplifies it into a PWM signal having a high level of about 5 to 40V. The amplification system 230 applies a low-pass filtering process to the PWM signal amplified to have such a high level, and outputs it to the loudspeaker 130.

Below, the amplification system 230 will be described in more detail.

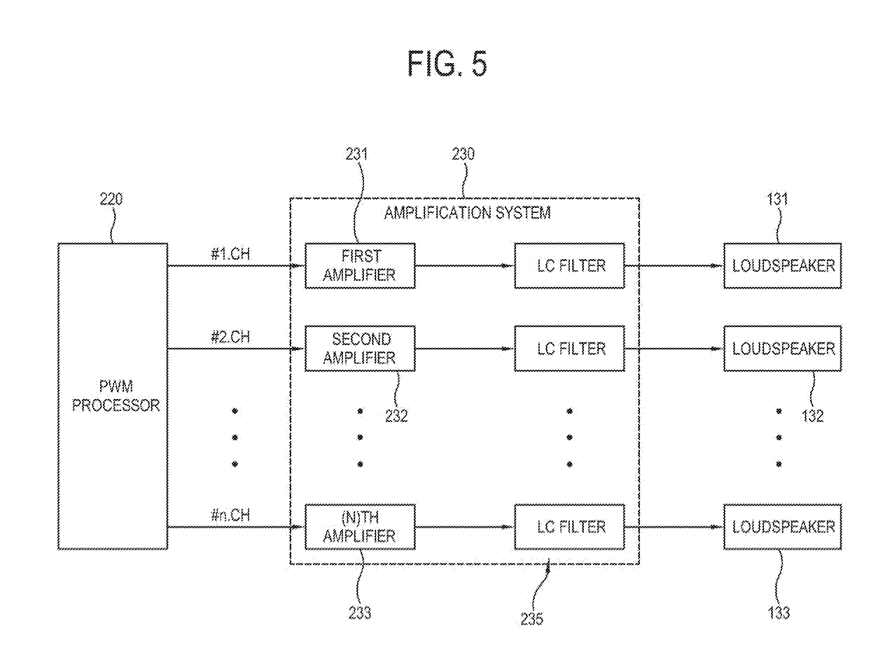

FIG. 5 is a block diagram of an amplification system 230.

As shown in FIG. 5, the amplification system 230 includes n amplifiers 231, 232 and 233. The amplifiers 231, 232 and 233 individually include LC filters 235, and output the processed audio signals to corresponding loudspeakers 131, 132 and 133, respectively. The number n of amplifiers 231, 232 and 233 refers to a channel limit of an audio signal that can be amplified by the amplification system 230. The amplification system 230 can support the output of the audio signal having channels of not more than n. For example, if n=6, the amplification system 230 can amplify and output the audio signal up to six channels. Of course, the number and kind of loudspeakers 131, 132 and 133 have to respectively correspond to the channels in order to normally output all the channels of the audio signal.

The PWM processor 220 applies the PWM signals to the respective amplifiers 231, 232 and 233. Then, the amplifiers 231, 232 and 233 amplify the PWM signals from the PWM processor 220 and output them to the LC filters 235, respectively. The LC filters 235 pass certain frequency bands of the amplified PWM signals in order to demodulate the PWM signal, and output the demodulated signals to the loudspeakers 131, 132 and 133, respectively. The respective loudspeakers 131, 132 and 133 produce sounds corresponding to the channels of the audio signal.

The amplifiers 231, 232 and 233 respectively corresponding to the channels basically use the FET to perform the amplification, and may have various circuit configurations. In accordance with the circuit configurations, the amplifiers 231, 232 and 233 may be designed to increase the energy efficiency or raise the output power.

Below, the circuit configuration of one among the amplifiers 231, 232 and 233 will be described by way of example.

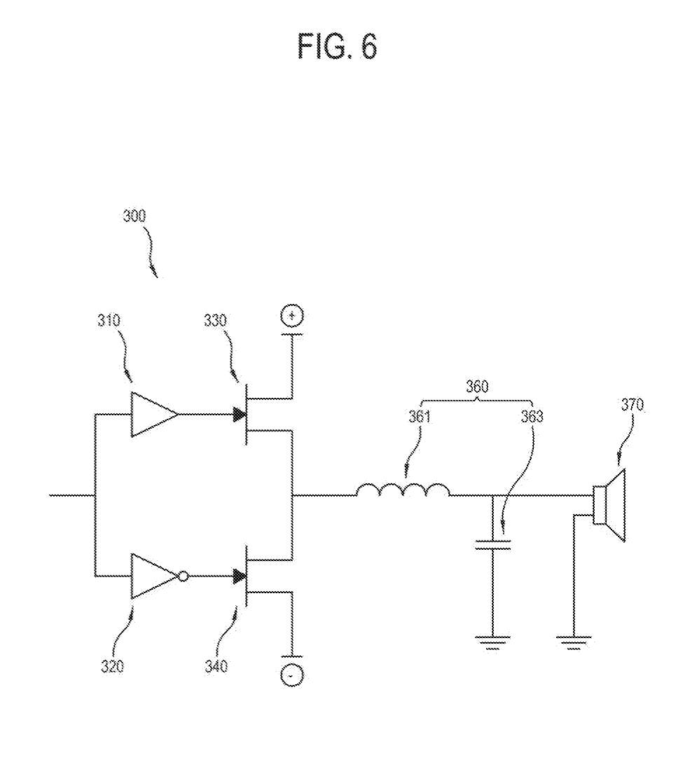

FIG. 6 is a circuit diagram of an amplifier 300 according to the first exemplary embodiment. The amplifier 300 of FIG. 6 may be applied to each of the amplifiers 231, 232 and 233 of FIG. 5.

As shown in FIG. 6, the amplifier 300 amplifies an input audio signal, and the LC filter 360 passes only a certain frequency band of the audio signal amplified by the amplifier 300 and outputs it to the loudspeaker 370. The amplifier 300 includes a buffer 310 for delaying the input audio signal, an inverter 320 for inverting a phase of the audio signal, and two FETs 330 and 340 arranged in parallel to amplify the audio signal output from the buffer 310 and the inverter 320.

The audio signal of a certain channel output from the PWM processor 220 (see FIG. 5) is branched into two paths. The buffer 310 and the inverter 320 are arranged in parallel, and the signals branched from the audio signal are respectively input to the buffer 310 and the inverter 320. The buffer 310 and the inverter 320 delay timing of transmitting the branched signals to the FETs 330 and 340 in accordance with signal processing operations of the amplifier 300. The branched signal output from the buffer 310 is input to an upper FET 330, and the branched signal output from the inverter 320 is input to a lower FET 340.

The FET refers to a device that controls an input voltage to change an output current. That is, an electric field is formed by voltage applied to the FET, and the output current is varied depending on the intensity of the electric field. In accordance with structures, the FET is classified into a metal oxide semiconductor field effect transistor (MOSFET) in which a control terminal is insulated by oxide, and a junction FET in which a control terminal is formed by a PN junction. Most recent semiconductor ICs generally employ a MOSFET, and a MOSFET is classified into an enhancement-type FET and a depletion-type FET.

The FET basically has three electrodes, i.e. a source electrode into which a carrier flows, a drain electrode from which a carrier flows out, and a gate electrode by which a passage width is determined when a carrier moves toward the drain. The FET is a device in which the electric current in the drain electrode is controlled by the voltage applied to the gate electrode.

For example, if voltage is applied between drain and source electrodes of an n-channel junction FET, electrons flow from the source electrode toward the drain electrode. Since negative voltage is applied to the gate electrode, holes in a p-type semiconductor are attracted to the gate electrode, and electrons in an n-type semiconductor are repelled by the negative voltage of the gate electrode, thereby increasing a depleted layer. When the depleted layer increases, the passage for the electrons becomes narrower and thus an electric current in the drain electrode is restricted. This depleted layer becomes thicker as reverse voltage gets higher and thus restricts flow of a main electric current.

The FET causes high input-impedance and low noise since a bias of reverse voltage is applied. Therefore, the FET has been used in low frequency amplification of low noise, frequency modulation (FM) of high frequency, high frequency amplification like that of a tuner of a TV, or high-speed switching.

The upper FET 330 and the lower FET 340 are connected in parallel with each other and connected in series with the LC filter 360. Specifically, the upper FET 330 has the source electrode connected to the drain electrode of the lower FET 340, the drain electrode to which the positive voltage is applied, and the gate electrode connected to the output terminal of the buffer 310. The lower FET 340 has the source electrode to which the negative voltage is applied, the drain electrode connected to the source electrode of the upper FET 330, and the gate electrode connected to the output terminal of the inverter 320.

With this structure, if an audio signal of ‘1’ is input to the amplifier 300, the buffer 310 provides a signal of ‘1’ to the upper FET 330 and thus the upper FET 330 is turned on. Further, the inverter 320 provides a signal of ‘0’ to the lower FET 340, and thus the lower FET 340 is turned off.

On the other hand, if an audio signal of ‘0’ is input to the amplifier 300, the buffer 310 provides a signal of ‘0’ to the upper FET 330 and thus the upper FET 330 is turned off. Further, the inverter 320 provides a signal of ‘1’ to the lower FET 340, and thus the lower FET 340 is turned on.

Such operations are performed in the amplifier 300 by PWM control in which signals of ‘0’ and ‘1’ are alternately input, and therefore the amplifier 300 amplifies the signal.

The LC filter 360 includes an inductor 361 and a capacitor 363 and passes or filters a signal having a certain frequency band. The LC filter 360 may serve as one of a low pass filter (LPF), a high pass filter (HPF) and a band pass filter (BPF) in accordance with combination of the inductor 361 and the capacitor 363.

According to this exemplary embodiment, the LC filter 360 functions as the LPF, in which the inductor 361 is connected in series with load and the capacitor 363 is connected in parallel with the inductor 361. A signal component of a low frequency band is allowed to pass through the LC filter 360. On the other hand, a signal component of a high frequency band is hard to pass through the LC filter 360 since high impedance of the inductor 361 causes low impedance of the capacitor 363.

The amplifier 300 according to this exemplary embodiment includes two FETs 330 and 340, which is called a single ended (SE) type amplifier 300. By the way, the output power of the SE type amplifier 300 is relatively low, and therefore does not cope with an audio volume higher than a certain level.

Below, a circuit, of which output power is higher than that of the amplifier 300 described in the first exemplary embodiment, will be described.

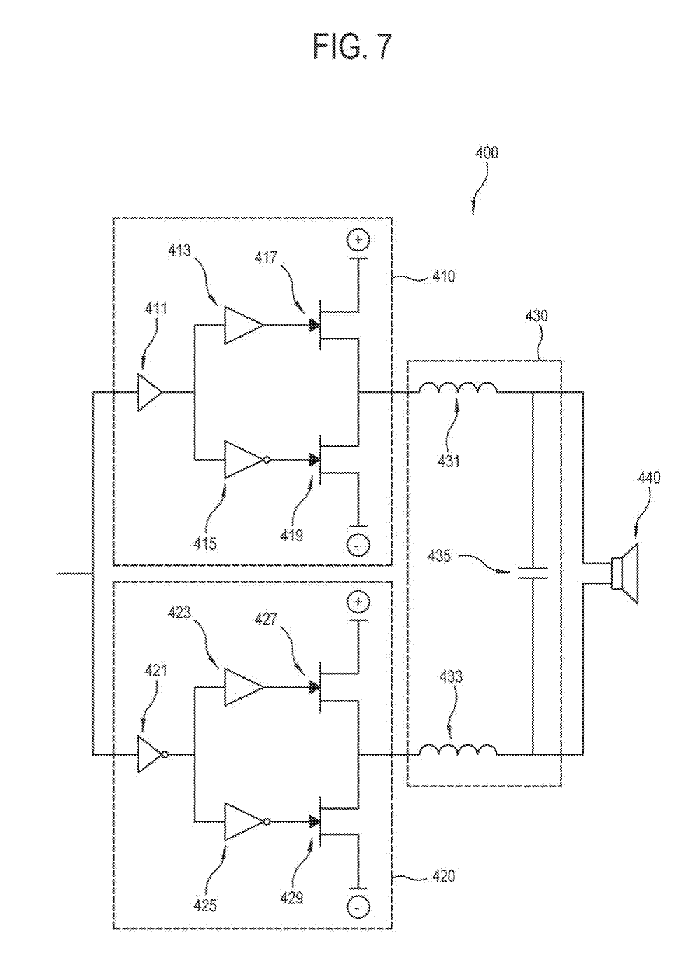

FIG. 7 is a circuit diagram of an amplifier 400 according to a second exemplary embodiment. Like the foregoing amplifier 300 of FIG. 6, the amplifier 400 of FIG. 7 may be also applied to the amplifiers 231, 232 and 233 of FIG. 5.

As shown in FIG. 7, the amplifier 400 according to the second exemplary embodiment includes a first sub-amplifier 410 for amplifying a first branched signal branched from the audio signal input to the amplifier 400, a second sub-amplifier 420 for amplifying a second branched signal branched from the audio signal input to the amplifier 400, and an LC filter 430 for amplifying the branched signals respectively output from the first sub-amplifier 410 and the second sub-amplifier 420 and outputting the amplified branched signal to a loudspeaker 440.

The first sub-amplifier 410 and the second sub-amplifier 420 are arranged in parallel with the LC filter 430 and the loudspeaker 440, and respectively receive the two branched signals branched from the audio signal. The LC filter 430 is a low pass filter that includes inductors 431 and 433 and a capacitor 435.

The basic structure of the first sub-amplifier 410 is similar to the structure of the amplifier 300 of FIG. 6. The first sub-amplifier 410 includes a buffer 411 to which the first branched signal of the audio signal is input, a buffer 413 and an inverter 415 to which two branched signals from the buffer 411 are respectively input, and an upper FET 417 and a lower FET 419 to which signals output from the buffer 413 and the inverter 415 are input.

The operations of the respective components are the same as those of the foregoing components described in FIG. 6, and thus repetitive descriptions will be avoided as necessary.

The second sub-amplifier 420 basically has the same structure as the first sub-amplifier 410, but includes an inverter 421 instead of the buffer 411 of the first sub-amplifier 410. The inverter 421 inverts the second branched signal of the audio signal, and the inverted second branched signal is branched again. The branched signals are respectively input to a buffer 423 and an inverter 425, and signals output from the buffer 423 and the inverter 425 are respectively input to the upper FET 427 and the lower FET 429.

With this structure, suppose that an audio signal of ‘1’ is input to the amplifier 400.

In the first sub-amplifier 410, the buffer 411 directly provides the audio signal of ‘1’ to the buffer 413 and the inverter 415. The buffer 413 provides the signal of ‘1’ to the upper FET 417 and therefore the upper FET 417 is turned on. Further, the inverter 415 provides a signal of ‘0’ to the lower FET 419 and therefore the lower FET 419 is turned off.

In the second sub-amplifier 420, the inverter 421 inverts the signal of ‘1’ into a signal of ‘0’. The buffer 423 provides the signal of ‘0’ to the upper FET 427 and thus the upper FET 427 is turned off. Further, the inverter 425 provides the signal of ‘1’ to the lower FET 429 and thus the lower FET 429 is turned on.

On the other hand, suppose that an audio signal of ‘0’ is input to the amplifier 400.

In the first sub-amplifier 410, the buffer 413 provides the signal of ‘0’ to the upper FET 417 and thus the upper FET 417 is turned off. Further, the inverter 415 provides the signal of ‘1’ to the lower FET 419 and thus the lower FET 419 is turned on.

In the second sub-amplifier 420, the inverter 421 inverts the signal of ‘0’ into a signal of ‘1’. The buffer 423 provides the signal of ‘1’ to the upper FET 427 and therefore the upper FET 427 is turned on. Further, the inverter 425 provides the signal of ‘0’ to the lower FET 429 and therefore the lower FET 429 is turned on.

In this embodiment, the amplifier 400 includes four FETs 417, 419, 427 and 429, and has a structure that the foregoing SE type amplifier 300 (see FIG. 6) of the first exemplary embodiment is arranged in parallel with two loads. This structure will be called a bridge-tied load (BTL) type amplifier.

Below, the SE type amplifier and the BTL type amplifier will be compared in terms of output power and energy efficiency.

The SE type amplifier includes two FETs, and operates using positive and negative voltages. If the input voltage is V and the impedance of the loudspeaker is I_{S}, the output power P_{SE} of the SE type amplifier is calculated by the following equation.

$${P}_{SE} = \frac{{( V / \sqrt{2} )}^{2}}{{I}_{S}} \qquad [ Equation 1 ]$$

On the other hand, the BTL type amplifier includes four FETs and operates using only a positive voltage or both positive and negative voltages. The output power P_{BTLs} of the BTL type amplifier using only the positive voltage is calculated by the following equation.

$${P}_{BTLs} = \frac{{( V / \sqrt{2} )}^{2}}{{I}_{S}} = {P}_{SE} \qquad [ Equation 2 ]$$

In addition, the output power P_{BTLd} of the BTL type amplifier using both the positive and negative voltages is calculated by the following equation.

$${P}_{BTLd} = \frac{{( 2 \times V / \sqrt{2} )}^{2}}{{I}_{S}} = 4 \times {P}_{SE} \qquad [ Equation 3 ]$$

There is little difference between the output power of the BTL type amplifier using only the positive voltage and the SE type amplifier. Therefore, the BTL type amplifier has to use both the positive and negative voltages in order to make the output power higher than that of the SE type amplifier.

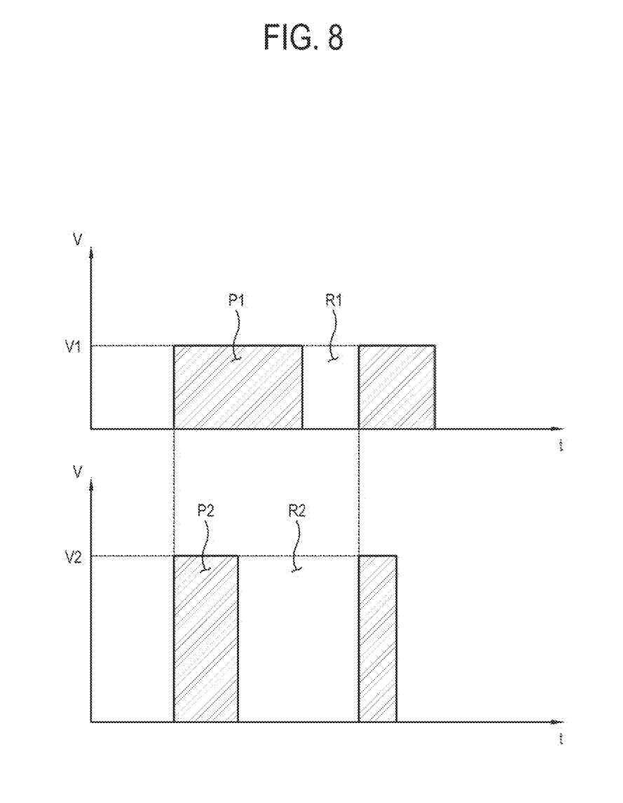

FIG. 8 is a graph showing respective output waveforms of the SE type amplifier and the BTL type amplifier if they have the same output power.

As shown in FIG. 8, the upper graph shows an output waveform of the SE type amplifier, and the lower graph shows an output waveform of the BTL type amplifier. Here, a horizontal axis t is time, and a vertical axis V is an applied voltage.

Referring to the two graphs, the areas of hatched portions P1 and P2 indicate the output power of the SE type amplifier and the output power of the BTL type amplifier. If the portion P1 has the same area as the portion P2, the respective amplifiers have the same output power.

If V1<V2 under the condition that the portion P1 has the same area as the portion P2, it means that the SE type amplifier uses a voltage having a lower level than that of the BTL type amplifier in order to make the same output power. In other words, if the output power is limited to a certain level or lower, the SE type amplifier has a higher energy efficiency than the BTL type amplifier.

On the other hand, if the output power is higher than the certain level, the BTL type amplifier can make the output power having the certain level, but the SE type amplifier cannot make the output power having the certain level. This is because there is a difference in area between the portion R1 and the portion R2 in the graphs.

The area of the portion R1 indicates a limit to enlargement of the portion P1, that is, a limit to increase of the output power in the SE type amplifier. Likewise, the area of the portion R2 indicates a limit to enlargement of the portion P2, that is, a limit to increase of the output power in the BTL type amplifier. If the area of the portion R1 is smaller than the area of the portion R2, the limit to the area of the portion P1 is smaller than the area of the portion P2. This means that the maximum output power of the SE type amplifier is lower than the maximum output power of the BTL type amplifier.

In terms of their circuits, the SE type amplifier uses two FETs, but the BTL type amplifier uses four FETs. That is, the amplifier using four FETs has higher amplification performance and higher energy loss than that using two FETs.

Therefore, with respect to the certain level of the output power, it is preferable that the BTL type amplifier is used for the output power higher than the certain level and the SE type amplifier is used for the output power lower than the output power equal to or lower than the certain level. However, it is uneconomical if a system includes both the SE type amplifier and the BTL type amplifier. Accordingly, there is a need of an improved structure for increasing the energy efficiency while using the amplifier based on the BTL type circuit structure in order to raise the output power.

Below, an improved structure will be described according to a third exemplary embodiment.

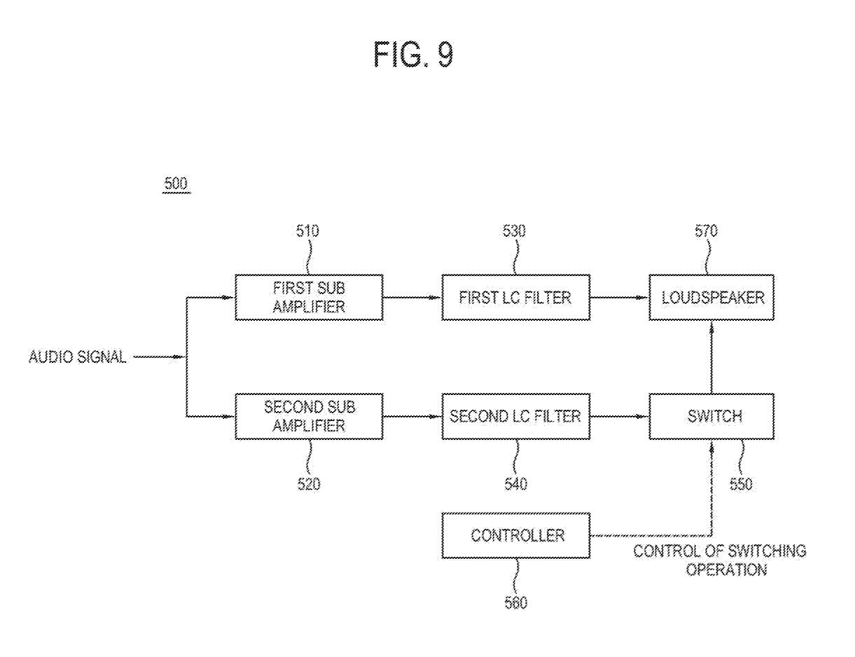

FIG. 9 is a block diagram of an amplification system 500 according to the third exemplary embodiment. The amplification system 500 of FIG. 9 may be applied to a structure corresponding to a certain channel of the audio signal in the amplification system 230 of FIG. 5.

As shown in FIG. 9, the amplification system 500 according to the third exemplary embodiment includes a first sub-amplifier 510 to which a first branched signal of the audio signal input to the amplification system 500 is input, a second sub-amplifier 520 to which a second branched signal of the audio signal input to the amplification system 500 is input, a first LC filter 530 to which an amplified signal output from the first sub-amplifier 510 is input, a second LC filter 540 to which an amplified signal output from the second sub-amplifier 520 is input, a switch 550 which selectively allows or prevents transmission of the audio signal from the second LC filter 540 to a loudspeaker 570, and a controller 560 which controls switching operations of the switch 550.

The first sub-amplifier 510 amplifies the first branched signal between two signals branched from the audio signal corresponding to a certain channel. The second sub-amplifier 520 amplifies the second branched signal between two signals branched from the corresponding audio signal. Here, the second sub-amplifier 520 inverts the second branched signal before amplifying it. That is, there is an antiphase relationship between the second sub-amplifier 520 and the first sub-amplifier 510.

The first LC filter 530 performs a low-pass filtering process to the audio signal amplified by the first sub-amplifier 510. Then, the audio signal filtered by the first LC filter 530 is input to the loudspeaker 570.

The second LC filter 540 performs a low-pass filtering process to the audio signal amplified by the second sub-amplifier 520. Here, the switch 550 allows or prevents the transmission of the audio signal from the second LC filter 540 to the loudspeaker 570 under control of the controller 560.

The controller 560 may be achieved by a microcontroller provided in the amplification system 500 or the signal processor (not shown), a CPU (not shown) of the signal processor (not shown). The controller 560 controls the switching operations of the switch 550 if a preset condition is satisfied or in response to a preset event.

The conditions for controlling the switching operations of the switch 550 may be variously set. For example, the controller 560 may control the switch 550 to allow the audio signal amplified by the second sub-amplifier 520 to be transmitted to the loudspeaker 570 if the output power of the amplification system 500 or the loudspeaker 570 is higher than a preset threshold level, and may control the switch 550 to prevent the audio signal amplified by the second sub-amplifier 520 from being transmitted to the loudspeaker 570 if the output power of the amplification system 500 or the loudspeaker 570 is not higher than the preset threshold level.

The output power is directly proportional to the audio volume of the loudspeaker 570. That is, the controller 560 controls the switch 550 to allow the audio signal amplified by the second sub-amplifier 520 to be transmitted to the loudspeaker 570 if the audio volume of the loudspeaker 570 is adjusted to be higher than the preset threshold level, and controls the switch 550 to prevent the audio signal amplified by the second sub-amplifier 520 from being transmitted to the loudspeaker 570 if the audio volume of the loudspeaker 570 is not higher than the preset threshold level. The audio volume may be adjusted by a user's input or other various events.

Below, the circuit structure of the amplification system 500 will be described in more detail.

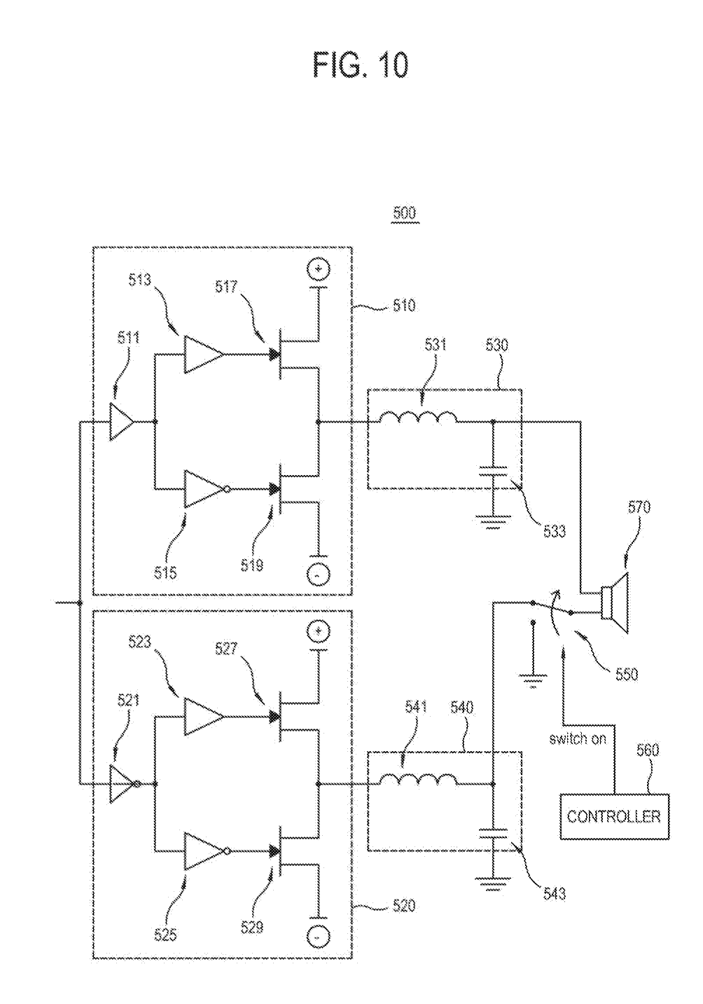

FIG. 10 is a circuit diagram of the amplification system 500 according to the third exemplary embodiment, showing an operation when an audio volume is higher than a threshold level.

As shown in FIG. 10, the amplification system 500 includes the first sub-amplifier 510, the second sub-amplifier 520, the first LC filter 530, the second LC filter 540, the switch 550 and the controller 560.

The first sub-amplifier 510 includes a buffer 511 to which the first branched signal of the audio signal is input, a buffer 513 and an inverter 515 to which branched by the buffer 511 are respectively input, an upper FET 517 to which a signal output from the buffer 513 is input, and a lower FET 519 to which a signal inverted by the inverter 515 is input.

Further, the second sub-amplifier 520 includes an inverter 521 to which the second branched signal of the audio signal is input, the buffer 523 and the inverter 525 to which signals branched by the inverter are respectively input, an upper FET 527 to which a signal output from the buffer 523 is input, and a lower FET 529 to which a signal inverted by and output from the inverter 525 is input.

The circuit structures and operations of the first sub-amplifier 510 and the second sub-amplifier 520 are substantially the same as those of the first sub-amplifier 410 (see FIG. 7) and the second sub-amplifier 420 (see FIG. 7), and thus detailed descriptions thereof will be omitted.

Further, the first LC filter 530 includes an inductor 531 and a capacitor 533, and the second LC filter 540 includes an inductor 541 and a capacitor 543. The circuit structure and operations of the first LC filter 530 and the second LC filter 540 are substantially the same as those described in the foregoing exemplary embodiments.

With this structure, suppose that the audio volume controlled by a user is higher than a preset threshold level. In response to a user's instruction, the controller 560 turns on the switch 550. Then, the signal output from the second LC filter 540 can be transmitted to the loudspeaker 570 through the switch 550.

In this state, suppose that the audio signal of ‘1’ is input to the first sub-amplifier 510 and the second sub-amplifier 520.

The signal of ‘1’ branched by and output from the buffer 511 is output from the buffer 513 as it is ‘1’, and inverted into a signal of ‘0’ by the inverter 515. In this case, the upper FET 517 is turned on and the lower FET 519 is turned off. Further, the signal of ‘0’ inverted by and output from the inverter 521 is output from the buffer 523 as it is ‘0’, and inverted into a signal of ‘1’ by the inverter 525. In this case, the upper FET 527 is turned off and the lower FET 529 is turned on.

On the other hand, suppose that the audio signal of ‘0’ is input to the first sub-amplifier 510 and the second sub-amplifier 520.

The signal of ‘0’ branched by and output from the buffer 511 is output from the buffer 513 as it is ‘0’, and inverted into ‘1’ by the inverter 515. In this case, the upper FET 517 is turned off and the lower FET 519 is turned on. Further, the signal of ‘1’ inverted by and output from the inverter 521 is output from the buffer 523 as it is ‘1’, and inverted into ‘0’ by the inverter 525. In this case, the upper FET 527 is turned on and the lower FET 529 is turned off.

The signals output from the upper FET 517 and the lower FET 519 are filtered by the first LC filter 530 and then transmitted to the loudspeaker 570.

Further, the signals output from the upper FET 527 and the lower FET 525 are filtered by the second LC filter 540. The filtered signals are transmitted from the second LC filter 540 to the loudspeaker 570 since the switch 550 is turned on by the controller 560.

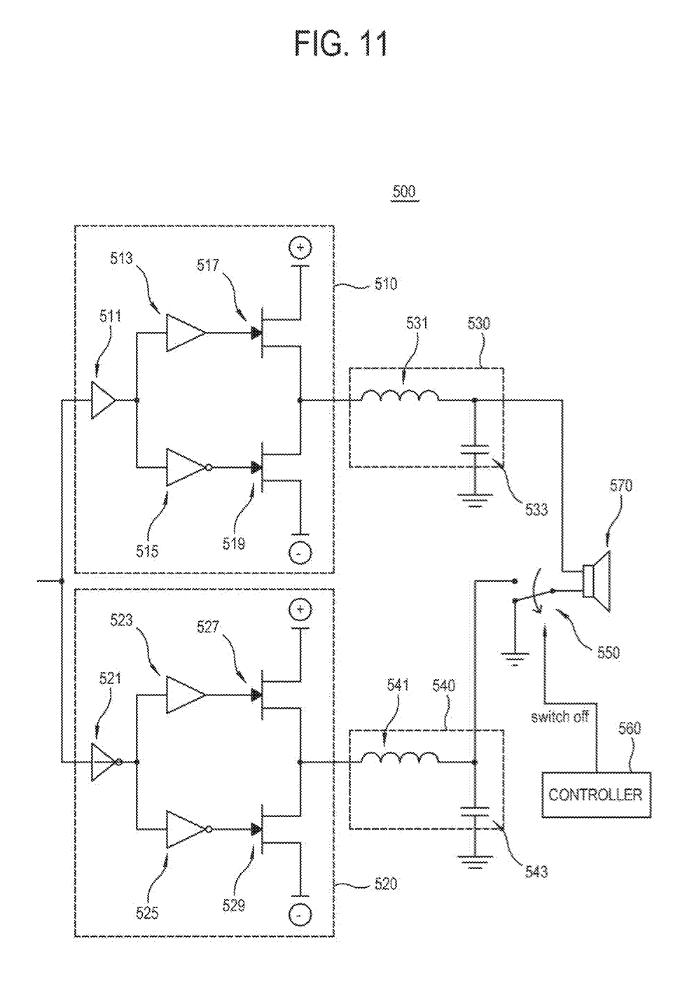

FIG. 11 is a circuit diagram of the amplification system 500 according to the third exemplary embodiment, showing an operation when the audio volume is equal to or lower than a threshold level;

As shown in FIG. 11, the amplification system 500 includes the first sub-amplifier 510, the second sub-amplifier 520, the first LC filter 530, the second LC filter 540, the switch 550 and the controller 560. The structure of the amplification system 500 is the same as those shown in FIG. 10, and thus repetitive descriptions thereof will be avoided as necessary.

Suppose that the audio volume adjusted by a user is not higher than the preset threshold level. In response to a user's instruction, the controller 560 turns off the switch 550. Thus, the switch 550 connected to an output terminal of the loudspeaker 570 is connected to the ground. Here, an input terminal between two connection terminals of the loudspeaker 570 is connected to the first LC filter 530, and the output terminal is connected to one of the second LC filter 540 and the ground by the switch 550. Therefore, the signal output from the second LC filter 540 is cut off at a front end of the switch 550.

The first sub-amplifier 510 operates as described with reference to FIG. 10 and amplifies the audio signal. The audio signal output from the first LC filter 530 is transmitted to the loudspeaker 570. On the other hand, the output terminals of the second sub-amplifier 520 and the second LC filter 540 are not connected to the loudspeaker 570, and one between two connection terminals of the loudspeaker 570 is connected to the ground. Therefore, the audio signals output from the second sub-amplifier 520 and the second LC filter 540 are not transmitted to the loudspeaker 570.

In the operation mode as shown in FIG. 10, both the first sub-amplifier 510 and the second sub-amplifier 520 are used and thus operate like the BTL type amplifier. On the other hand, in the foregoing operation mode as shown in FIG. 11, only the first sub-amplifier 510 is used and thus operates like the SE type amplifier. For convenience of description, the operation mode of FIG. 10 will be called a BTL mode, and the operation mode of FIG. 11 will be called an SE mode.

That is, the amplification system 500 according to this exemplary embodiment operates in the BTL mode similarly to the BTL type amplifier if the audio volume is adjusted to be higher than the preset threshold level, thereby raising the output power. On the other hand, the amplification system 500 operates in the SE mode similarly to the SE type amplifier if the audio volume is adjusted not to be higher than the threshold level, thereby enhancing the energy efficiency. In particular, if the video processing apparatus is achieved by a mobile apparatus or installed in an electric vehicle, it is possible to reduce battery consumption.

Below, operations according an exemplary embodiment will be described.

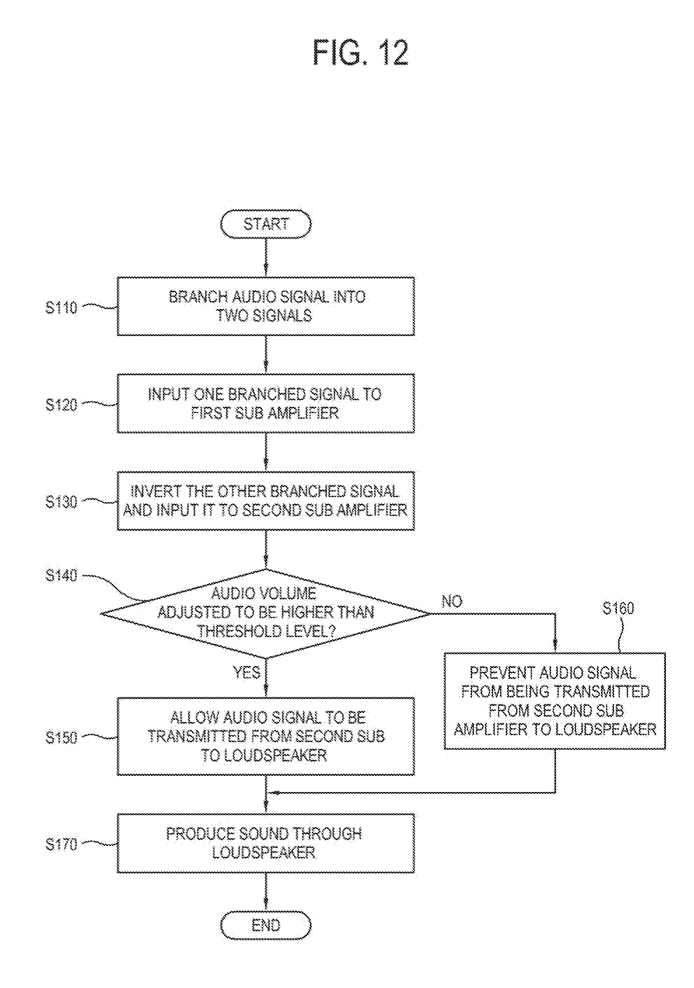

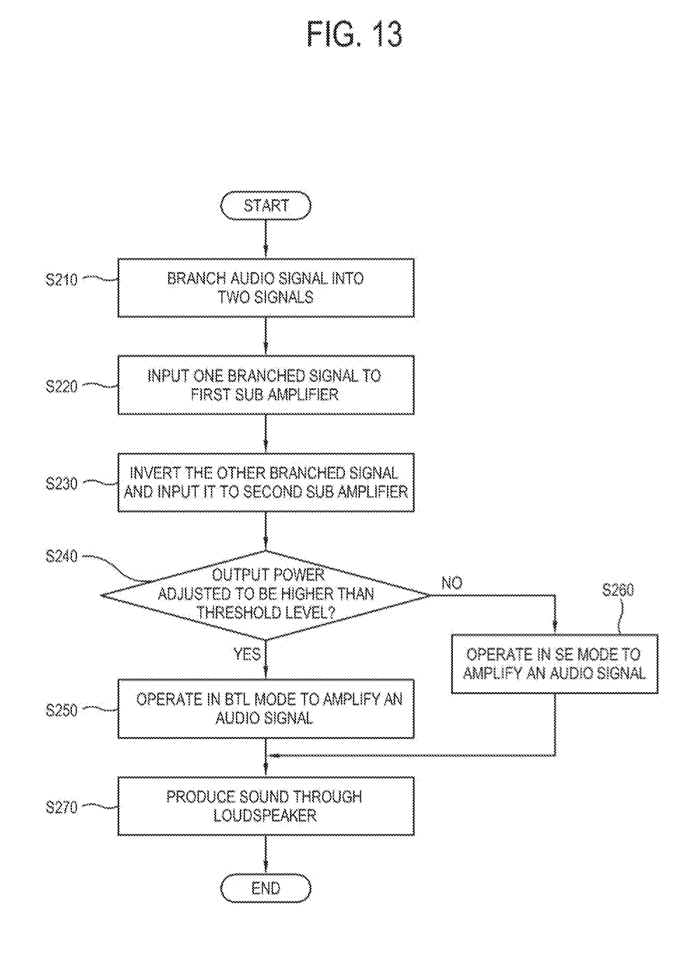

FIGS. 12 and 13 are flowcharts showing that the amplification system of the video processing apparatus according to the third exemplary embodiment amplifies an audio signal of a certain channel to control a sound output through a loudspeaker. In FIG. 12 and FIG. 13, the operations according the present exemplary embodiment are alternatively expressed.

As shown in FIG. 12, at operation S110 the amplification system branches the audio signal into two signals.

At operation S120 the amplification system inputs one branched audio signal to a first sub-amplifier. At operation S130 the amplification system inverts the phase of the other branched audio signal and then inputs it to the second sub-amplifier.

At operation S140 the amplification system determines whether a user adjusts the audio volume to be higher than the threshold level.

If it is determined that the audio volume is adjusted to be higher than the threshold level, at operation S150 the amplification system allows the audio signal to be transmitted from the second sub-amplifier to the loudspeaker.

On the other hand, if it is determined that the audio volume is adjusted not to be higher than the threshold level, at operation S160 the amplification system prevents the audio signal from being transmitted from the second sub-amplifier to the loudspeaker.

At operation S170 the amplification system makes the loudspeaker produce a sound based on the audio signal transmitted to the loudspeaker.

As shown in FIG. 13, at operation S210 the amplification system branches the audio signal into two signals.

At operation S220 the amplification system inputs one branched audio signal to the first sub-amplifier. At operation S230 the amplification system inverts the phase of the other branched audio signal and then inputs it to the second sub-amplifier.

At operation S240 the amplification system determines whether a user adjusts the audio volume to be higher than the threshold level.

If it is determined that the audio volume is adjusted to be higher than the threshold level, at operation S250 the amplification system operates in the BTL mode where both the first sub-amplifier and the second sub-amplifier are used for amplifying the audio signal.

On the other hand, if it is determined that the audio volume is adjusted not to be higher than the threshold level, at operation S260 the amplification system operates in the SE mode where only the first sub-amplifier between the first sub-amplifier and the second sub-amplifier is used for amplifying the audio signal.

At operation S270 the amplification system makes the loudspeaker produce a sound based on the audio signal transmitted to the loudspeaker.

As a criterion of a switching operation between the BTL mode and the SE mode, the threshold level may be determined in accordance with a variety of factors such as the types of the amplification system, the environments of the loudspeaker, etc. Thus, there are no limits to the threshold level. However, as one method of determining the threshold level, the threshold level may be determined in terms of the maximum output power in the BTL mode and the energy efficiency in the SE mode, and this will be described below.

In the amplification system, four FETs are activated in the BTL mode, and two FETs are activated in the SE mode. The positive and negative voltages are all used in both the BTL mode and the SE mode. Under the same conditions of the input voltage, the impedance of the loudspeaker and the performance of each FET, the SE mode has a higher energy efficiency than the BTL mode as described above with reference to FIG. 8. However, the SE mode supports the output power lower than that of the BTL mode, and therefore the amplification system has to operate in the BTL mode if the output power is required to be higher than a certain level. Therefore, this level may be used as the threshold level for the criterion of the switching operation between the SE mode and the BTL mode.

Specifically, as described in the foregoing equations 1 and 3, the output power of the amplification system is determined by the input voltage and the impedance of the loudspeaker. Under the same conditions of the input voltage and the impedance of the loudspeaker, the output power of the amplification system in the BTL mode is four times higher than that in the SE mode. In other words, the maximum output power of the amplification system in the SE mode is a quarter of that in the BTL mode.

Accordingly, the threshold level may be determined as a quarter of the maximum output power of the amplification system in the BTL mode. That is, the amplification system operates in the BTL mode if the adjusted output power is higher than a quarter of the maximum output power in the BTL mode, and operates in the SE mode if the adjusted output power is equal to or lower than a quarter of the maximum output power in the BTL mode.

However, a theoretical level may be not applicable due to a variety of factors related to the circuit when the apparatus is actually materialized. Although the threshold level is a quarter of the maximum output power in the BTL mode of the amplification system, a preset increase value may be reflected to this threshold level. When the amplification system is actually realized, a range from a quarter of the maximum power in the BTL mode to the preset value is ambiguous in terms of comparison between the energy efficiency and the output power. Thus, the threshold level may be determined as a certain value within this range, for example, as ½ of the maximum output power in the BTL mode of the amplification system.

Accordingly, the amplification system operates to make desired output power if the desired output power is higher the threshold level, but operates to enhance the energy efficiency if the desired output power is equal to or lower than the threshold level.

In the foregoing third exemplary embodiment, the controller 560 (see FIG. 9) controls the switching operation of the switch 550 (see FIG. 9). However, the controller 560 (see FIG. 9) may control the second sub-amplifier 520 (see FIG. 9) to be turned on and off in addition to the switching operation of the switch 550 (see FIG. 9).

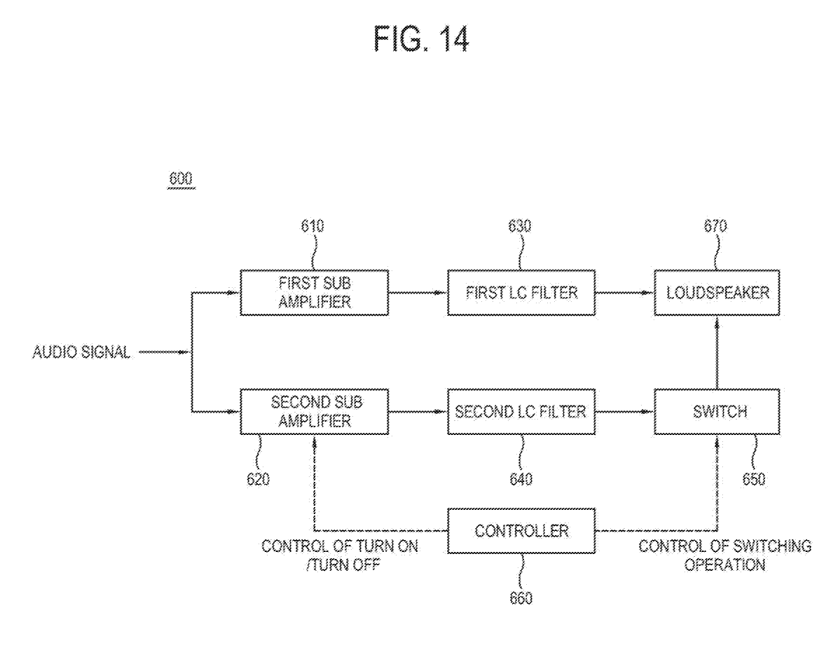

FIG. 14 is a block diagram of an amplification system 600 according to a fourth exemplary embodiment.

As shown in FIG. 14, the amplification system 600 includes a first sub-amplifier 610, a second sub-amplifier 620, a first LC filter 630, a second LC filter 640, a switch 650, and a controller 660. These elements of the amplification system 600 according to the fourth exemplary embodiment are substantially the same as those shown in FIG. 9 according to the third exemplary embodiment, and thus detailed descriptions thereof will be omitted.

This exemplary embodiment is different from the third exemplary embodiment as follows.

If it is determined that a user adjusts an audio volume to be higher than a threshold level, the controller 660 controls the switch 650 to allow the audio signal to be transmitted from the second LC filter 640 to a loudspeaker 670, and activates the second sub-amplifier 620. To this end the controller 660 transmits a turn-on signal to the second sub-amplifier 620 and thus turns on the second sub-amplifier 620. Consequently, the amplification system 600 operates in the BTL mode.

On the other hand, if it is determined that a user adjusts the audio volume not to be higher than the threshold level, the controller 660 controls the switch 650 to prevent the audio signal from being transmitted from the second LC filter 640 to the loudspeaker 670, and inactivates the second sub-amplifier 620. To this end the controller 660 transmits a turn-off signal to the second sub-amplifier 620 and thus turns off the second sub-amplifier 620. Consequently, the amplification system 600 operates in the SE mode.

In other words, the controller 660 controls the second sub-amplifier 620 to be activated and inactivated while controlling the switching operation of the switch 650, thereby reducing energy consumption in the second sub-amplifier 620. In this exemplary embodiment, the energy consumption is more reduced than that in the foregoing third exemplary embodiment.

The controller 660 performs control to turn on and off the second sub-amplifier 620, and the second LC filter 640 is not controlled to be activated and inactivated by the controller 660 since it is a passive element.

Below, control operations of the amplification system according to this exemplary embodiment will be described.

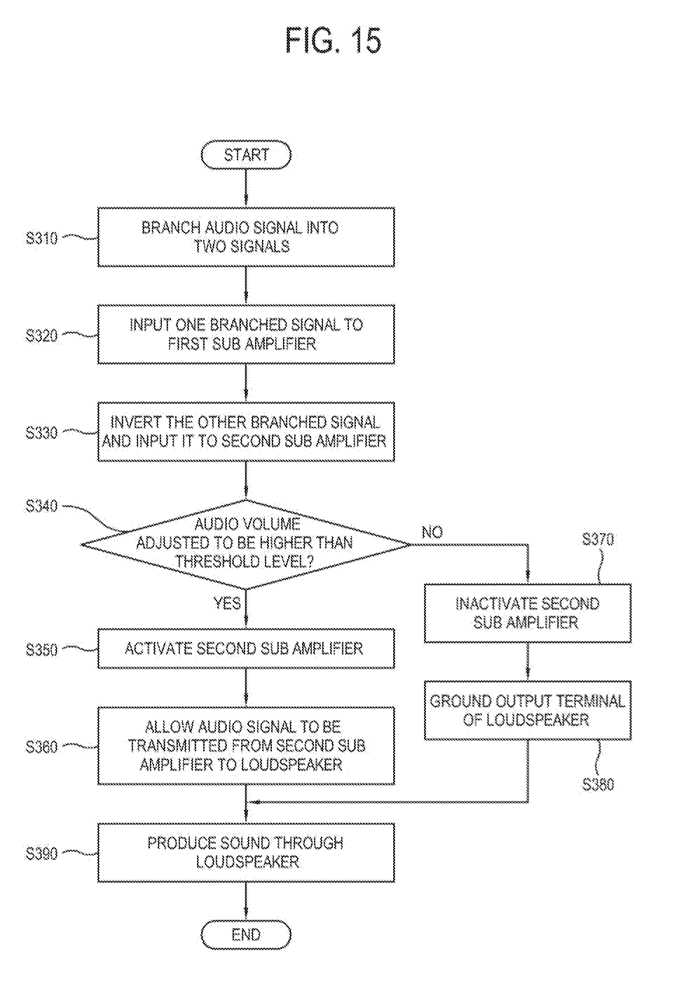

FIG. 15 is a flowchart showing that the amplification system according to the fourth exemplary embodiment amplifies an audio signal of a certain channel to control a sound output through a loudspeaker.

As shown in FIG. 15, at operation S310 the amplification system branches the audio signal into two signals.

At operation S320 inputs one branched audio signal to a first sub-amplifier. At operation S330 the amplification system inverts the phase of the other branched audio signal and then inputs it to the second sub-amplifier.

At operation S340 the amplification system determines whether a user adjusts the audio volume to be higher than the threshold level.

If it is determined that the audio volume is adjusted to be higher than the threshold level, at operation S350 the amplification system activates the second sub-amplifier

At operation S360 the amplification system allows the audio signal to be transmitted from the second sub-amplifier to the loudspeaker.

On the other hand, if it is determined that the audio volume is adjusted not to be higher than the threshold level, at operation S370 the amplification system inactivates the second sub-amplifier. At operation S380 the amplification system connects the output terminal of the loudspeaker to the ground.

At operation S390 the amplification system makes the loudspeaker produce a sound based on the audio signal transmitted to the loudspeaker.

In the foregoing exemplary embodiments, the amplification system selectively operates in the BTL mode or the SE mode in accordance with whether the audio volume or the output power is adjusted to be higher than the preset threshold level. However, the threshold level or condition for determining the operation mode of the amplification system is not limited to this exemplary embodiment. Below, an alternative exemplary embodiment will be described.

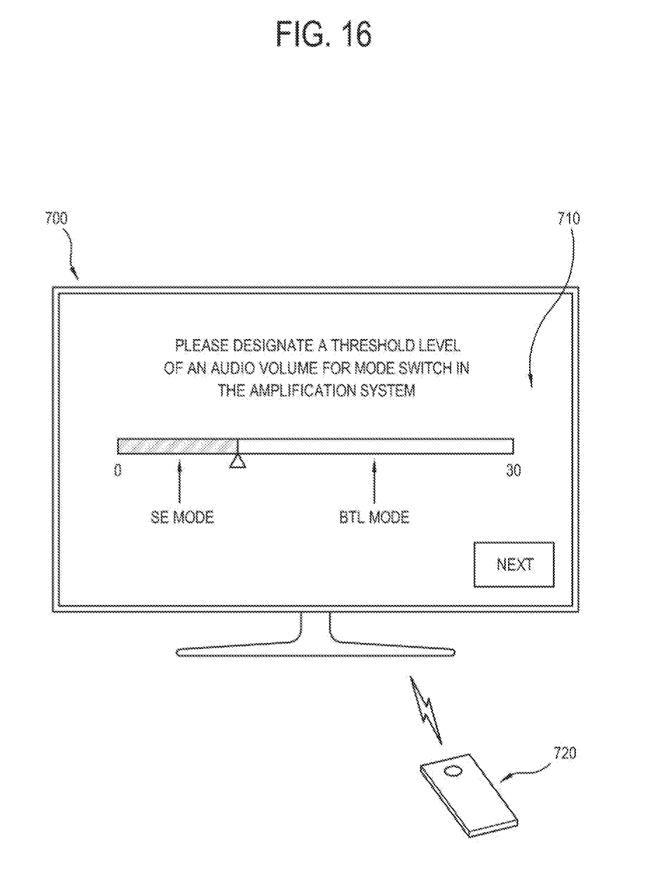

FIG. 16 illustrates a user interface (UI) 710 of adjusting a threshold level for determining an operation mode of an amplification system in a video processing apparatus 700;

As shown in FIG. 16, the video processing apparatus 700 according to the fifth exemplary embodiment displays the UI 710 in accordance with certain instructions from a user input 720.

The UI 710 guides a user to designate the threshold level of the audio volume so that the amplification system for amplifying the sound of the video processing apparatus 700 can determine one between the BTL mode for raising the output power and the SE mode for enhancing the energy efficiency. The UI 710 may be provided with a slide bar so that a user can easily designate a certain volume level, or may be provided to make a user directly input a certain numerical value.

Basically, the video processing apparatus 700 may have a default value for the threshold level, and shows this default value as an initial value when the UI 710 is displayed. Thus, a user may change the initial value through the UI 710.

When a certain audio volume is designated through the UI 710, the video processing apparatus 700 stores the designated value for the audio volume as the threshold level. In the future, if a user adjusts the audio volume to a certain level through the user input 720, the video processing apparatus 700 determines whether the adjusted volume is higher than the previously stored threshold level, and operates in one of the BTL mode and the SE mode in accordance with determined results.

Below, control operations of the video processing apparatus will be described.

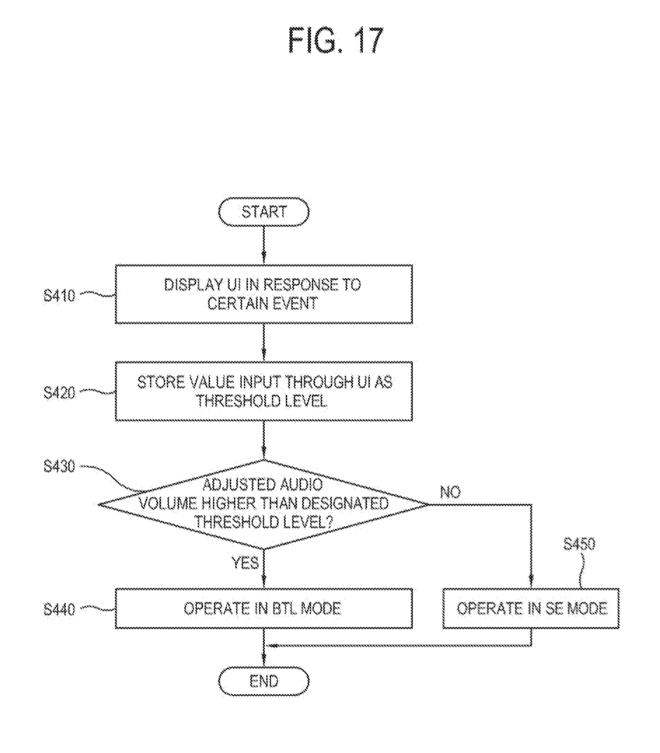

FIG. 17 is a flowchart showing control of the video processing apparatus according to the fifth exemplary embodiment.

As shown in FIG. 17, at operation S410 the video processing apparatus displays a UI in response to a certain event. At operation S420 the video processing apparatus stores a numerical value input through the UI as the threshold level.

At operation S430 the video processing apparatus determines whether the adjusted audio volume is higher than the threshold level.

If the adjusted audio volume is higher than the threshold level, at operation S440 the video processing apparatus operates in the BTL mode. On the other hand, if the adjusted audio volume is not higher than the threshold level, at operation S450 the video processing apparatus operates in the SE mode.

Accordingly, it is easy for a user to set the threshold level for switching the audio amplification mode.

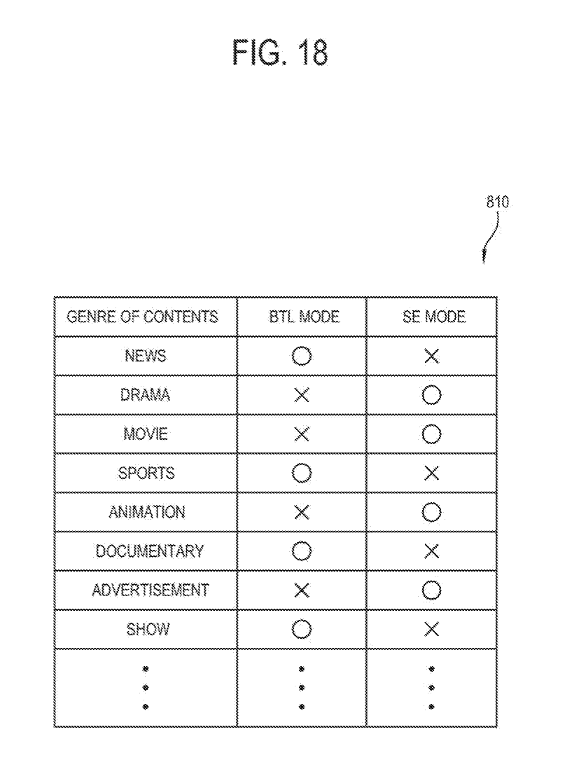

FIG. 18 shows a table where operation modes of an amplification system are set according to genres of contents in a video processing apparatus according to a sixth exemplary embodiment.

As shown in FIG. 18, the video processing apparatus processes data of video contents to display an image. The video contents may be classified according to various categories, for example, genres. The genres of video contents may for example include news, drama, movie, sports, animation, documentary, advertisement, show, etc., and this genre may also be subdivided.

Taking the characteristics of the genre or other reasons into account, the video contents may be divided into a case of requiring a relatively high audio volume and a case of requiring a relatively low audio volume. For example, the news and the documentary for exact information delivery may be set to have a relatively high audio volume. Further, the sports and the show may be set to have a relatively high audio volume in order to convey a sense of realism. In addition, the movie, the drama, the animation, the advertisement or the like may be set to have a relatively low audio volume since a high audio volume may turn attention away from them. Of course, this example may be varied depending on designs or a user's tastes.

The video processing apparatus stores a table 810, in which one of the BTL mode and the SE mode is designated corresponding to whether the genre of the video content are set to have a relatively high audio volume or a relatively low audio volume.

The video processing apparatus determines the genre of the video contents when receiving the video contents. The video processing apparatus may determine the genre based on meta information extracted from the video contents or may determine the genre by retrieving information from an electronic program guide (EPG) based on the title and the other information of the video contents.

The video processing apparatus retrieves the genre determined as above from the table 810, and determines which mode corresponds to the genre. The video processing apparatus uses the determined mode to amplify a sound while displaying an image based on the video contents.

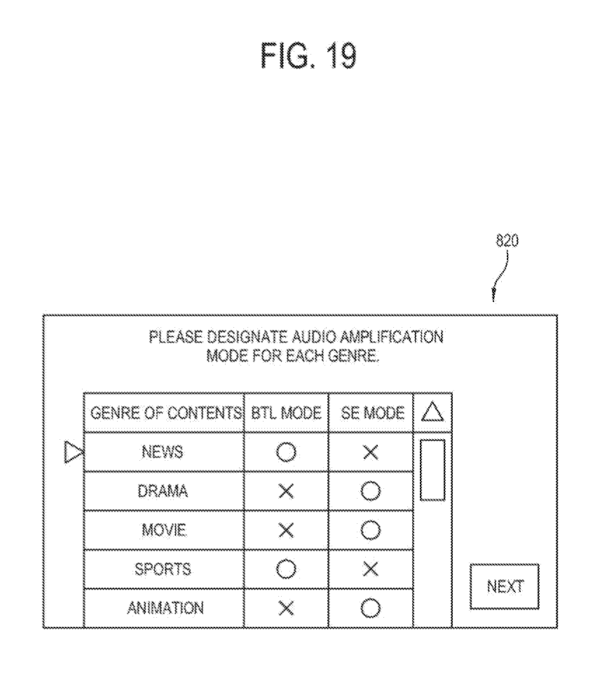

FIG. 19 illustrates a UI 820 of adjusting the table where the operation modes of the amplification system are set according to the genres of the contents in the video processing apparatus according to the sixth exemplary embodiment.

As shown in FIG. 19, the video processing apparatus may display the UI 820 through which a user can adjust detailed options of the foregoing table 810 (see FIG. 18). For example, someone may feel that the genre of the sports is too loud and thus wants the SE mode even though the default mode for the genre of the sports is the BTL mode in the table 810.

Thus, a user can adjust an operation mode of a certain genre through the UI 820. The video processing apparatus modifies the options of the table 810 (see FIG. 18) in response to an input through the UI 820.

According to this exemplary embodiment, the genre of the video contents is determined, and the mode is determined corresponding to the determined genre. However, information about the video contents is not limited to only the genre, and therefore the video processing apparatus may determine the mode in accordance with various pieces of information related to the video contents.

Below, a control method of the video processing apparatus according to this exemplary embodiment will be described.

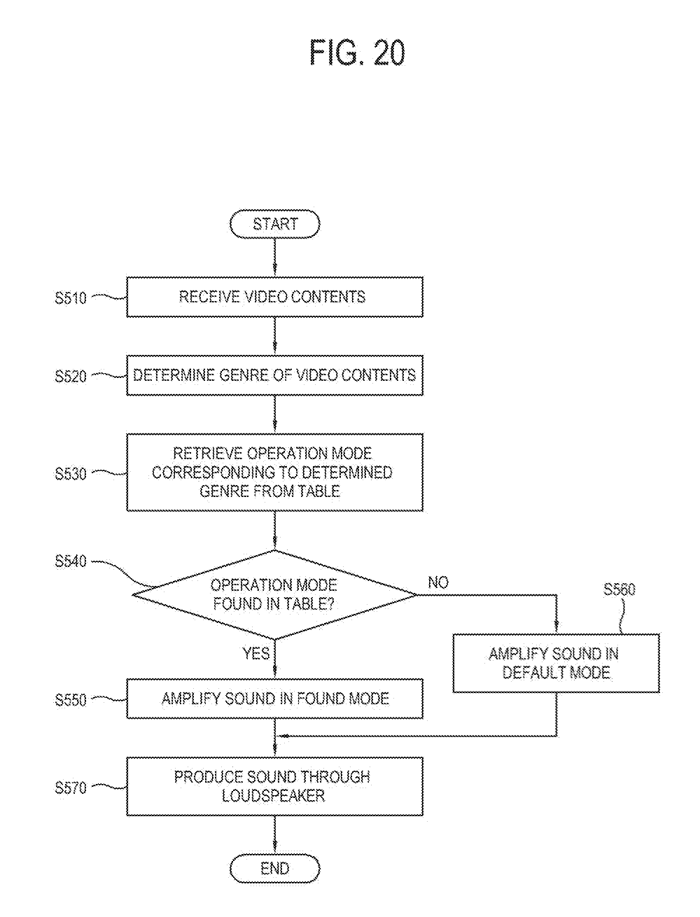

FIG. 20 is a flowchart showing control of the video processing apparatus according to the sixth exemplary embodiment.

As shown in FIG. 20, at operation S510 the video processing apparatus receives video contents. At operation S520 the video processing apparatus determines the genre of the video contents.

At operation S530 the video processing apparatus retrieves the operation mode corresponding to the determined genre from the previously stored table.

At operation S540 the video processing apparatus determines whether the corresponding mode is found in the table.

If the mode corresponding to the genre is found in the table, at operation S550 the video processing apparatus amplifies a sound in the retrieved mode.

On the other hand, if the mode corresponding to the genre is not found in the table, at operation S560 the video processing apparatus amplifies a sound in one of the BTL mode and the SE mode designated as a default mode. In this case, the video processing apparatus may display a UI for designating the mode corresponding to the genre, and operate in the mode designated in the UI.

At operation S570 the video processing apparatus produces a sound through the loudspeaker.

In the foregoing exemplary embodiment, the audio amplification mode is selected according to the genres, but not limited thereto. Alternatively, the audio volume may be determined in accordance with display time of the video contents regardless of the genres. In general, a relatively low audio volume may be preferred from 8 PM to 8 AM of the next day corresponding to night and dawn, and a relatively high audio volume may be preferred from 8 AM to 8 PM of the day. The video processing apparatus may select the audio amplification mode in accordance with this condition, and such an exemplary embodiment will be described below.

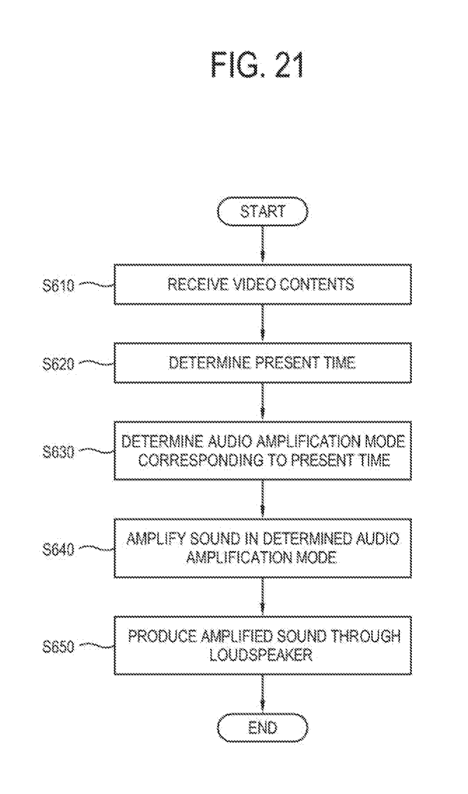

FIG. 21 is a flowchart showing control of a video processing apparatus according to a seventh exemplary embodiment;

As shown in FIG. 21, at operation S610 the video processing apparatus receives the video contents.

At operation S620 the video processing apparatus determines the present time. Here, if the video processing apparatus is connected to a network, it may acquire information about the present time by accessing a certain server. Alternatively, the video processing apparatus may determine the present time from a built-in clock.

At operation S630 the video processing apparatus determines the audio amplification mode corresponding to the determined present time. For example, the audio amplification mode may be previously set in the video processing apparatus so that the video processing apparatus can operate in the SE mode by night and in the BTL mode by day. Alternately, the SE mode or the BTL mode may be set according to time zones.

At operation S640 the video processing apparatus amplifies a sound based on the determined audio amplification mode. At operation S650 the video processing apparatus outputs the amplified sound through the loudspeaker.

Additionally, the video contents currently provided to a user may be produced in various countries and expressed by different languages. Of course, the video contents may be dubbed in a user's own language and then given, but are usually given in their original languages without dubbing.

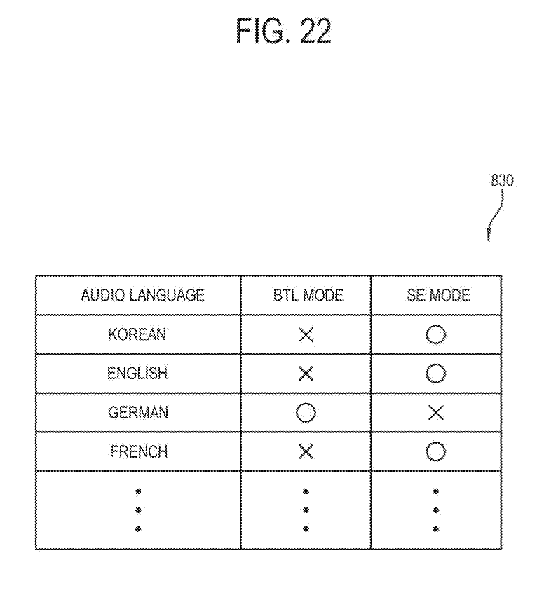

FIG. 22 shows a table where audio amplification modes are set according to audio languages of video contents in a video processing apparatus according to an eighth exemplary embodiment

As shown in FIG. 22, if a user's native language is Korean and the video contents are given in Korean, it is not difficult for him/her to understand the sound of the video contents even through the audio volume is relatively low. Likewise, if a user is well-versed in English and the video contents are given in English, it is not difficult for him/her to understand the sound of the video contents even through the audio volume is relatively low.

On the other hand, in a case where a user has some knowledge of German and the video contents are given in German, she or he can understand the sound of the video contents to some extent only if the audio volume is relatively high, and it is not easy for him/her to understand the sound if the audio volume is relatively low.

In addition, if a user does not know anything about French and the video contents are given in French, she or he cannot understand the sound of the video contents regardless of whether the audio volume is high or low.

Accordingly, the video processing apparatus may previously store a table 830 where the audio amplification mode is set according to languages. As described above, the sound given in a user's native language or a language in which she or he is versed is easily understood by him/her even though the audio volume is low, and therefore the SE mode is preferable. The sound given in a language about which a user does not know anything is not understood by him/her regardless of whether the audio volume is high or low, and therefore the SE mode is preferable in terms of energy efficiency. On the other hand, the audio volume has to be high for easily understanding the sound given in a language of which a user has some knowledge, and therefore the BTL mode is preferable.

The video processing apparatus selects the audio amplification mode of the video contents in accordance with settings of the table 830 where the modes are designated corresponding to the languages, and amplifies and outputs the sound in the selected mode.

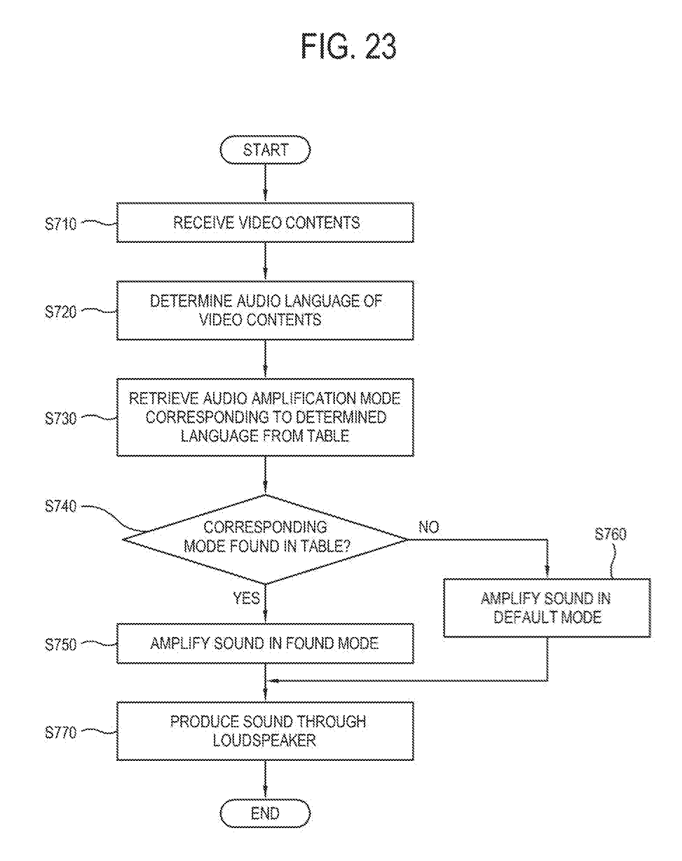

FIG. 23 is a flowchart showing control of the video processing apparatus according to the eighth exemplary embodiment.

As shown in FIG. 23, at operation S710 the video processing apparatus receives the video contents. At operation S720 the video processing apparatus determines an audio language of the video contents.

At operation S730 the video processing apparatus retrieves the audio amplification mode corresponding to the determined language from the table.

At operation S740 the video processing apparatus determines whether the mode corresponding to the language is found in the table.

If the mode corresponding to the language is found in the table, at operation S750 the video processing apparatus amplifies the sound in the retrieved mode.

On the other hand, if the mode corresponding to the language is not found in the table, at operation S760 the video processing apparatus amplifies the sound in the default mode. Alternatively, the video processing apparatus may display a UI through which the mode can be selected corresponding to the language, and amplify the sound in the mode selected through the UI.

At operation S770 the video processing apparatus outputs the amplified sound to the loudspeaker.

In the foregoing exemplary embodiments, the present inventive concept is applied to the video processing apparatus. However, the present inventive concept may be applied to an apparatus, in which an audio process is possible but a video process is impossible, as well as the display apparatus capable of displaying an image by itself or the video processing apparatus capable of processing an image to be displayed. Of course, this apparatus may support another process in addition to the audio process.

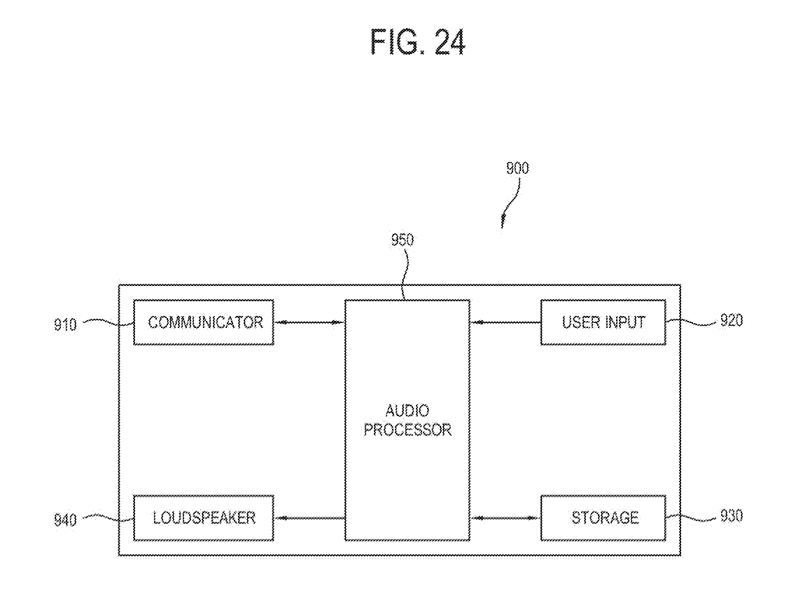

FIG. 24 is a block diagram of an audio processing apparatus 900 according to a ninth exemplary embodiment.

As shown in FIG. 24, the audio processing apparatus 900 according to the ninth exemplary embodiment includes a communicator 910 for communicating with the exterior, a user input 920 for receiving a user's input, a storage 930 for storing data, a loudspeaker 940 for producing a sound, and an audio processor 950 for processing a sound to be produced by the loudspeaker 940.

Basic functions and operations of these elements are substantially the same as those of the foregoing exemplary embodiments, and thus repetitive descriptions thereof will be avoided as necessary. The audio processor 950 amplifies audio data received in the communicator 910 or stored in the storage 930 so that the loudspeaker 940 can produce a sound based on the audio data. In this procedure, the audio processor 950 operates in one of the BTL mode and the SE mode in accordance with audio output power.

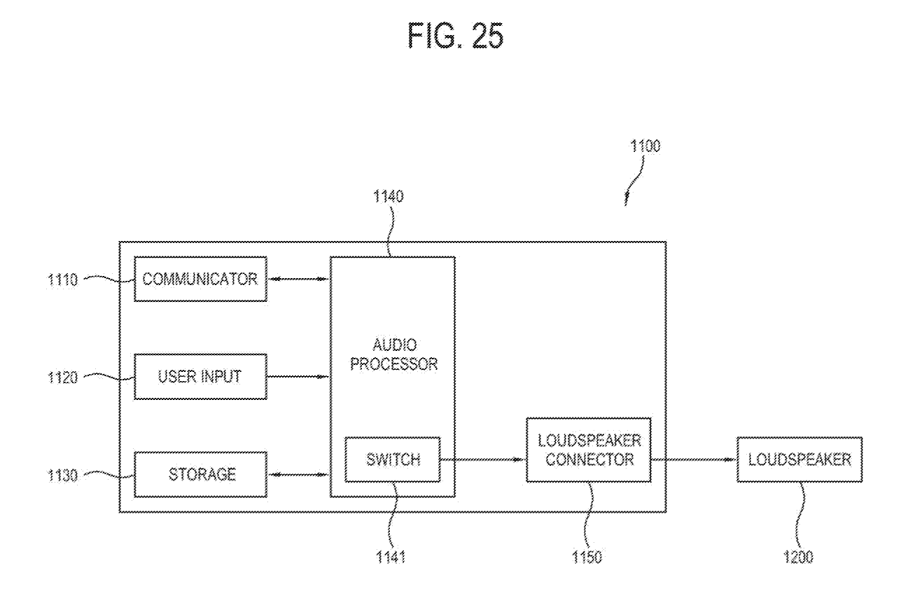

FIG. 25 is a block diagram of an audio processing apparatus 1100 according to a tenth exemplary embodiment.

As shown in FIG. 25, the audio processing apparatus 1100 according to the tenth exemplary embodiment includes a communicator 1110 for communicating with the exterior, a user input 1120 for receiving a user's input, a storage 1130 for storing data, and an audio processor 1140 for processing audio data.

Basic operations of the audio processing apparatus 1100 are substantially the same as those of the foregoing exemplary embodiments. However, the audio processing apparatus 1100 does not include a loudspeaker 1200, but includes a loudspeaker connector 1150 to which the loudspeaker 1200 is locally connected. The audio processor 1140 outputs an amplified audio signal to the external loudspeaker 1200 through the loudspeaker connector 1150 so that the loudspeaker 1200 can produce a sound.

In this case, a switch 1141, which operates as described in the foregoing exemplary embodiments, may be connected to the loudspeaker connector 1150, thereby selectively switching electric connection between the audio processor 1140 and an output terminal of the loudspeaker 1200. The operation of the switch 1141 and the related switching operation of the audio processor 1140 between the BTL mode and the SE mode are substantially the same as those of the foregoing exemplary embodiments, and thus detailed descriptions thereof will be omitted.

The methods according to the foregoing exemplary embodiments may be achieved in the form of a program command that can be implemented in various computers, and recorded in a computer readable medium. Such a computer readable medium may include a program command, a data file, a data structure or the like, or combination thereof. For example, the computer readable medium may be stored in a voltage or nonvolatile storage such as a read only memory (ROM) or the like, regardless of whether it is deletable or rewritable, for example, a RAM, a memory chip, a device or integrated circuit (IC) like memory, or an optically or magnetically recordable or machine (e.g., a computer)-readable storage medium, for example, a compact disk (CD), a digital versatile disk (DVD), a magnetic disk, a magnetic tape or the like. It will be appreciated that a memory, which can be included in a mobile terminal, is an example of the machine-readable storage medium suitable for storing a program having instructions for materializing the exemplary embodiments. The program command recorded in this storage medium may be specially designed and configured according to the exemplary embodiments, or may be publicly known and available to those skilled in the art of computer software.

Although a few exemplary embodiments have been shown and described, it will be appreciated by those skilled in the art that changes may be made in these exemplary embodiments without departing from the principles and spirit of the invention, the scope of which is defined in the appended claims and their equivalents.

What is claimed is:

1. An audio processing apparatus comprising:
a signal receiver to receive a content signal;
a first amplifier to output a first amplified signal of an audio signal extracted from the content signal;
a second amplifier to output a second amplified signal of the audio signal, which has an inverted phase of the first amplified signal;
a loudspeaker to produce a sound corresponding to the audio signal;
a switch to perform a switching operation so that at least one of the first amplified signal and the second amplified signal respectively amplified by and output from the first amplifier and the second amplifier can be selectively transmitted to the loudspeaker; and
at least one processor configured to control the switching operation of the switch in accordance with a level of output power of the sound.

2. The audio processing apparatus according to claim 1, wherein the at least one processor controls the switch to allow the second amplified signal to be transmitted from the second amplifier to the loudspeaker if the level of the output power is adjusted to be higher than a preset threshold level, and controls the switch to prevent the switch to prevent the second amplified signal from being transmitted from the second amplifier to the loudspeaker if the level of the output power is adjusted not to be higher than the threshold level.

3. The audio processing apparatus according to claim 2, wherein the threshold level for the at least one processor is a quarter of the maximum level of the output power of when both the first amplified signal and the second amplified signal are transmitted to the loudspeaker.

4. The audio processing apparatus according to claim 1, wherein the at least one processor activates the second amplifier to perform an amplifying operation if the level of the output power is adjusted to be higher than the preset threshold level, and inactivates the second amplifier not to perform the amplifying operation if the level of the output power is adjusted not to be higher than the threshold level.

5. The audio processing apparatus according to claim 1, wherein the loudspeaker comprises a first terminal for receiving the first amplified signal and a second terminal for receiving the second amplified signal, and
the at least one processor controls the switch to electrically connect the second terminal and the second amplifier if the level of the output power is adjusted to be higher than the preset threshold level, and controls the switch to connect the second terminal and the ground if the level of the output power is adjusted not to be higher than the preset threshold level.

6. The audio processing apparatus according to claim 1, wherein each of the first amplifier and the second amplifier comprises two field effect transistors (FETs), and
the two FETs comprises a first FET and a second FET, in which a source electrode of the first FET and a drain electrode of the second FET are connected in series with each other.

7. The audio processing apparatus according to claim 1, wherein the at least one processor processes a positive voltage and a negative voltage to be all applied to the first amplifier and the second amplifier.

8. The audio processing apparatus according to claim 1, further comprising a user input,
wherein the level of the output power corresponds to an audio volume adjusted through the user input.

9. A method of controlling an audio processing apparatus, the method comprising:
receiving a content signal;
outputting a first amplified signal of an audio signal extracted from the content signal by a first amplifier;
outputting a second amplified signal of the audio signal, which has an inverted phase of the first amplified signal, by a second amplifier;
performing a switching operation by a switch in accordance with a level of output power of the sound so that at least one of the first amplified signal and the second amplified signal respectively amplified by and output from the first amplifier and the second amplifier can be selectively transmitted to a loudspeaker; and
producing a sound corresponding to the audio signal by the loudspeaker.

10. The method according to claim 9, wherein the performing the switching operation by the switch comprises:
allowing the second amplified signal to be transmitted from the second amplifier to the loudspeaker if the level of the output power is adjusted to be higher than a preset threshold level; and
preventing the switch to prevent the second amplified signal from being transmitted from the second amplifier to the loudspeaker if the level of the output power is adjusted not to be higher than the threshold level.

11. The method according to claim 10, wherein the threshold level is a quarter of the maximum level of the output power of when both the first amplified signal and the second amplified signal are transmitted to the loudspeaker.

12. The method according to claim 9, further comprising:
activating the second amplifier to perform an amplifying operation if the level of the output power is adjusted to be higher than the preset threshold level; and
inactivating the second amplifier not to perform the amplifying operation if the level of the output power is adjusted not to be higher than the threshold level.

13. The method according to claim 9, wherein the loudspeaker comprises a first terminal for receiving the first amplified signal and a second terminal for receiving the second amplified signal, and
the performing the switching operation by the switch comprises
electrically connecting the second terminal and the second amplifier if the level of the output power is adjusted to be higher than the preset threshold level, and
connecting the second terminal and the ground if the level of the output power is adjusted not to be higher than the preset threshold level.

14. The method according to claim 9, wherein a positive voltage and a negative voltage are all applied to the first amplifier and the second amplifier.

15. The method according to claim 9, wherein the level of the output power corresponds to an audio volume adjusted through a user input.

16. An audio/video (AV) processing system comprising:
a signal receiver for receiving a transport stream;
a display for displaying an image based on video data of the transport stream;
a loudspeaker for producing a sound based on audio data of the transport stream;
a user input for receiving a user's input;
a storage for storing data; and
a signal processor including an audio processor to process the audio data,
wherein the audio processor comprises
a first amplifier to output a first amplified signal of the audio data;
a second amplifier to output a second amplified signal of the audio data, which has an inverted phase of the first amplified signal;
a switch to perform a switching operation so that at least one of the first amplified signal and the second amplified signal respectively amplified by and output from the first amplifier and the second amplifier can be selectively transmitted to the loudspeaker in accordance with a level of output power of the sound.

17. The AV processing system according to claim 16, further comprising at least one processor,
wherein the at least one processor is configured to control the switch to allow the second amplified signal to be transmitted from the second amplifier to the loudspeaker when the level of the output power is adjusted to be higher than a preset threshold level, and to control the switch to prevent the switch to prevent the second amplified signal from being transmitted from the second amplifier to the loudspeaker when the level of the output power is adjusted not to be higher than the threshold level.

18. The AV processing system according to claim 17, wherein the threshold level for the at least one processor is a quarter of the maximum level of the output power of when both the first amplified signal and the second amplified signal are transmitted to the loudspeaker.

19. The AV processing system according to claim 16, wherein the at least one processor is configured to activate the second amplifier to perform an amplifying operation when the level of the output power is adjusted to be higher than the preset threshold level, and inactivates the second amplifier not to perform the amplifying operation when the level of the output power is adjusted not to be higher than the threshold level.

20. The AV processing system according to claim 16, wherein the level of the output power corresponds to an audio volume adjusted through the user input.
